(19) United States
(12) Patent Application Publication
(10) Pub. No.: US 2025/0100101 A1
(43) Pub. Date: Mar. 27, 2025

(54) BUFFING TREATMENT MODULE INCLUDING BUFFING PAD

(71) Applicant: SAMSUNG ELECTRONICS CO., LTD., Suwon-si (KR)

(72) Inventors: Seungyoon Kim, Suwon-si (KR); Eunkyoung Kim, Suwon-si (KR); Boumyoung Park, Suwon-si (KR); Hyodong Lee, Suwon-si (KR)

(21) Appl. No.: 18/732,911

(22) Filed: Jun. 4, 2024

(30) Foreign Application Priority Data
Sep. 26, 2023 (KR) 10-2023-0129571

(51) Int. Cl. B24B 37/26

(52) U.S. Cl. CPC B24B 37/26

(57) ABSTRACT

A buffing treatment module includes: a buffing table that supports a substrate; a buffing head located on the buffing table and configured to rotate; and a buffing pad attached to a lower part of the buffing head and rotating while in contact with the substrate for performing buffing treatment on the substrate, wherein the buffing pad includes: a base unit; a plurality of protrusion units that protrude from a surface of the base unit and are spaced apart from each other in a circumferential direction of the base unit; and a plurality of trench units positioned adjacent to the plurality of protrusion units, and extending from a center portion of the base unit to an edge portion of the base unit, wherein the plurality of trench units are spaced apart from each other in the circumferential direction of the base unit.

### CROSS-REFERENCE TO RELATED APPLICATION

This application claims priority under 35 U.S.C. § 119 to Korean Patent Application No. 10-2023-0129571, filed on Sep. 26, 2023, in the Korean Intellectual Property Office, the disclosure of which is incorporated by reference herein in its entirety.

### TECHNICAL FIELD

Embodiments of the present inventive concept relate to a buffing treatment module including a buffing pad, and more particularly, to a buffing treatment module including a buffing pad capable of removing scratches or small particles from a substrate (or a wafer).

### DISCUSSION OF THE RELATED ART

Generally, when manufacturing semiconductor devices, a chemical mechanical polishing (CMP) process using a CMP treatment system may be used to planarize the substrate or the wafer. Due to a high integration of semiconductor devices and the large diameter of the substrate, the CMP treatment system may typically include a buffing treatment module that additionally polishes or cleans the substrate to more precisely planarize the surface of the substrate.

### SUMMARY

According to an embodiment of the present inventive concept, a buffing treatment module includes: a buffing table that supports a substrate; a buffing head located on the buffing table and configured to rotate; and a buffing pad attached to a lower part of the buffing head and rotating while in contact with the substrate for performing buffing treatment on the substrate, wherein the buffing pad includes: a base unit; a plurality of protrusion units that protrude from a surface of the base unit and are spaced apart from each other in a circumferential direction of the base unit; and a plurality of trench units positioned adjacent to the plurality of protrusion units, and extending from a center portion of the base unit to an edge portion of the base unit, wherein the plurality of trench units are spaced apart from each other in the circumferential direction of the base unit.

According to an embodiment of the present inventive concept, a buffing treatment module includes: a buffing table that supports a substrate; a buffing head located on the buffing table and configured to rotate; and a buffing pad attached to a lower part of the buffing head and rotating while in contact with the substrate for performing buffing treatment on the substrate, wherein the buffing pad includes: a base unit having an outer circle and an inner circle that is located within the outer circle; a plurality of protrusion units that protrude from a surface of the base unit, and that extend to a boundary of the inner circle, wherein the plurality of protrusion units are spaced apart from each other in a circumferential direction of the base unit; and a plurality of trench units positioned adjacent to the plurality of protrusion units, and extending from the inner circle to the outer circle, wherein the plurality of trench units are spaced apart from each other in the circumferential direction of the base unit.

According to an embodiment of the present inventive concept, a buffing treatment module includes: a buffing table that supports a substrate; a buffing head located on the buffing table and configured to rotate; and a buffing pad attached to a lower part of the buffing head and rotating while in contact with the substrate for performing buffing treatment on the substrate, wherein the buffing pad includes: a circular base unit having an outer circle and an inner circle that is located within the outer circle; a plurality of protrusion units that protrude from a surface of the base unit, and that extend to a boundary of the inner circle, wherein the plurality of protrusion units are spaced apart from each other in a circumferential direction of the base unit; a plurality of trench units positioned adjacent to the plurality of protrusion units, and extending from the inner circle to the outer circle, wherein the plurality of trench units are spaced apart from each other; and a central trench unit connected to the plurality of trench units inside the inner circle.

### BRIEF DESCRIPTION OF THE DRAWINGS

The above and other aspects of the present inventive concept will become more apparent by describing in detail embodiments thereof, with reference to the accompanying drawings, in which:

FIG. 1 is a schematic plan view of a chemical mechanical polishing (CMP) treatment system including a buffing treatment module according to an embodiment of the present inventive concept;

FIG. 2 is a schematic perspective view of the configuration of the buffing treatment module of FIG. 1;

FIG. 3 is a schematic cross-sectional view of the internal structure of a buffing head of FIG. 2;

FIG. 4 is a plan view of a buffing pad included in a buffing treatment module according to an embodiment of the present inventive concept;

FIG. 5 is a cross-sectional view taken along line A-A′ of FIG. 4;

FIG. 6 is a plan view of a buffing pad included in a buffing treatment module according to an embodiment of the present inventive concept;

FIG. 7 is a cross-sectional view taken along line B-B′ of FIG. 6;

FIG. 8 is a plan view of a buffing pad included in a buffing treatment module according to an embodiment of the present inventive concept;

FIG. 9 is a cross-sectional view taken along line C-C′ of FIG. 8;

FIG. 10 is a plan view of a buffing pad included in a buffing treatment module according to an embodiment of the present inventive concept;

FIG. 11 is a plan view of a buffing pad included in a buffing treatment module according to an embodiment of the present inventive concept;

FIG. 12 is a plan view of a buffing pad included in a buffing treatment module according to an embodiment of the present inventive concept;

FIG. 13 is a plan view of a buffing pad included in a buffing treatment module according to an embodiment of the present inventive concept;

FIG. 14 is a plan view of a buffing pad included in a buffing treatment module according to an embodiment of the present inventive concept;

FIG. 15 is a plan view of a buffing pad included in a buffing treatment module according to an embodiment of the present inventive concept;

FIG. 16 is a cross-sectional view of a buffing pad included in a buffing treatment module according to an embodiment of the present inventive concept;

FIG. 17 is a cross-sectional view of a buffing pad included in a buffing treatment module according to an embodiment of the present inventive concept; and

FIG. 18 is a cross-sectional view of a buffing pad included in a buffing treatment module according to an embodiment of the present inventive concept.

### DETAILED DESCRIPTION OF THE EMBODIMENTS

Hereinafter, embodiments of the present inventive concept are described in detail with reference to the attached drawings. One of the following embodiments of the present inventive concept may be implemented, or one or more of the following embodiments of the present inventive concept may also be implemented in combination. Accordingly, the present inventive concept should not be construed as being limited to one embodiment.

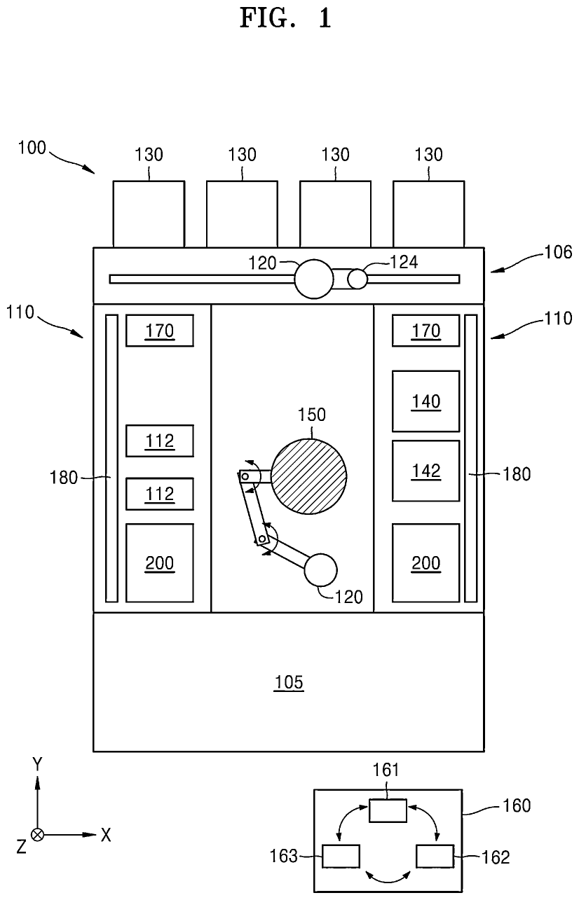

FIG. 1 is a schematic plan view of a chemical mechanical polishing (CMP) treatment system including a buffing treatment module according to an embodiment of the present inventive concept.

For example, a CMP treatment system 100 may be used to polish and clean a surface of a substrate 120 when manufacturing semiconductor devices. The arrangement of each component constituting the CMP treatment system 100 shown in FIG. 1 does not limit the present inventive concept. The arrangement of each component constituting the CMP treatment system 100 may be configured in various ways.

The CMP treatment system 100 may include a first portion 105 and a second portion 106 that is coupled to the first portion 105. The first portion 105 including a plurality of polishing stations may be a portion for main polishing of the substrate 120. The second portion 106 including various components may be a portion for additional polishing, cleaning, and drying of the substrate 120.

The second portion 106 may include one or more cleaning systems 110, a plurality of system loading stations 130, a first substrate handler 124 and 150, and a second substrate handler 180. The first substrate handler 124 and 150 may include a first robot 124 and a second robot 150.

The cleaning system 110 may include a vertical cleaning module 112, a metrology station 140, a location specific polishing module 142, and a buffing treatment module 200. The vertical cleaning module 112 may be configured to clean the substrate 120 that is arranged in a vertical direction, i.e., a Z-Y plane. In embodiments of the present inventive concept, the vertical cleaning module 112 may be located below the buffing treatment module 200, the metrology station 140, or the location specific polishing module 142 in a Z direction.

The location specific polishing module 142 may be configured to polish a portion of the surface of the substrate 120 by using a polishing member that has a surface area that is less than the surface area of the substrate 120 that is to be polished. For example, the location specific polishing module 142 may polish only a portion of the surface of the substrate 120. The location specific polishing module 142 may be used to additionally polish a small area of the surface of the substrate 120 after polishing the substrate 120. The buffing treatment module 200 may be configured to buff, for example, polish or clean the substrate 120 that is arranged in a horizontal direction, i.e., an X-Y plane. The buffing treatment module 200 may be referred to as a horizontal cleaning module.

The metrology station 140 may measure a thickness of a material layer that is disposed on the substrate 120 before or after polishing. The metrology station 140 may inspect the substrate 120 after polishing or inspect the surface of the substrate 120 for defects before or after polishing. The substrate 120 may be moved to a polishing module within the first portion 105 or to the location specific polishing module 142 for additional polishing based on measurement or surface inspection results obtained using the metrology station 140.

The first robot 124 may transfer the substrate 120 between the system loading stations 130 and the second robot 150 or between the cleaning system 110 and the system loading stations 130. In embodiments of the present inventive concept, the first robot 124 may transfer the substrate 120 between one of the system loading stations 130 and components located proximately thereto. For example, the first robot 124 may transfer the substrate 120 between one of the system loading stations 130 and the metrology station 140.

The second robot 150 may be used to transfer the substrate 120 between the first portion 105 and the second portion 106. The second robot 150 may transfer the substrate 120, which is to be polished and is received from the first robot 124, to the first portion 105. The second robot 150 may transfer the polished substrate 120 from the first portion 105 to a component within the second portion 106. For example, the second robot 150 may transfer the substrate 120 from the first portion 105 to one of the location specific polishing module 142, the metrology station 140, or the buffing treatment module 200. The second robot 150 may transfer the substrate 120 between different components located within the second portion 106. The second robot 150 may transfer the substrate 120 from either the location specific polishing module 142 or the metrology station 140 to the first portion 105 for additional polishing in the first portion 105.

The buffing treatment module 200 may be arranged within the second portion 106 at a position that is proximate to the first portion 105. The substrate 120 may be placed horizontally within the buffing treatment module 200. The buffing treatment module 200 may perform a pre-cleaning process, for example, a buffing treatment, on the substrate 120.

The second substrate handler 180 may position the substrate 120 at a vertical position for additional treatment in the vertical cleaning module 112. For example, the second substrate handler 180 may swing the substrate 120 to the vertical position. The vertical cleaning module 112 may be located in the second portion 106. The vertical cleaning module 112 may be a contact and non-contact cleaning system for removing polishing byproducts from the surfaces of the substrate 120, for example, any one of a spray box and/or a brush box, or a combination thereof.

A drying unit 170 is used to dry the substrate 120 before the substrate 120 is transferred by the first robot 124 to the system loading station 130. The drying unit 170 may be a unit that dries the substrate 120 while the substrate 120 is arranged in the horizontal direction. The substrate 120 may be transferred between the buffing treatment module 200 and the vertical cleaning module 112 and between the cleaning module 112 and the drying unit 170 by using the second substrate handler 180.

The CMP treatment system 100 may be operated by a system controller 160. The system controller 160 may include a programmable central processing unit (CPU) 161 operable with memory 162 and support circuitry 163. The support circuitry 163 may be coupled to the programmable CPU 161. For example, the support circuitry 163 may include cache, clock circuits, input/output subsystems, power suppliers, etc., and combinations thereof to facilitate control of the various components of the CMP treatment system 100.

For example, the CPU 161 may be any type of general-purpose computer processor, such as a programmable logic controller (PLC), used in the industrial field to control various components and sub-processors of a treatment system. For example, the memory 162 coupled to the CPU 161 may be one or more of readily available memories, such as random access memory (RAM), read-only memory (ROM), a floppy disk drive, a hard disk, or any other form of local or remote digital storage. The memory 162 may be a computer-readable storage medium (e.g., non-volatile memory) including instructions that facilitate operation of the CMP treatment system 100 when executed by the CPU 161.

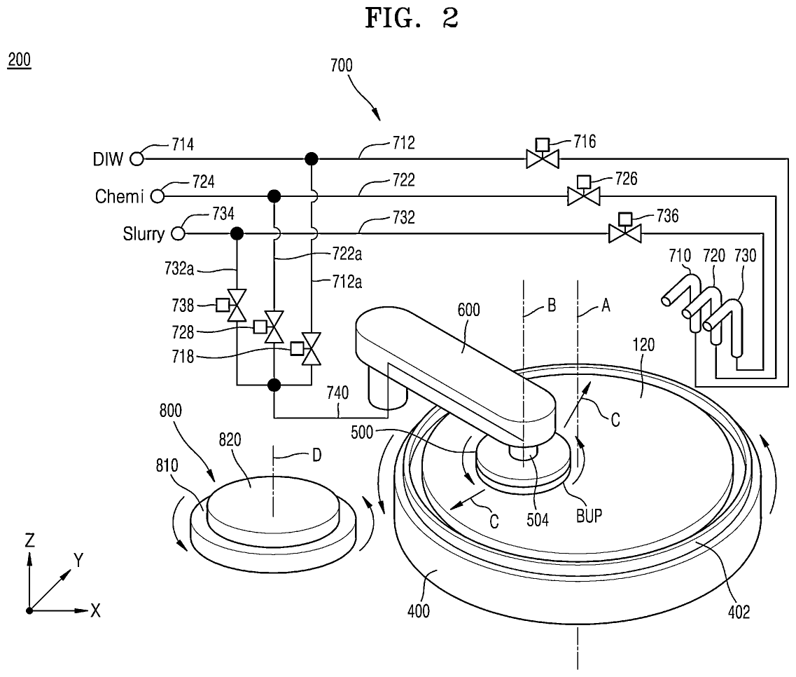

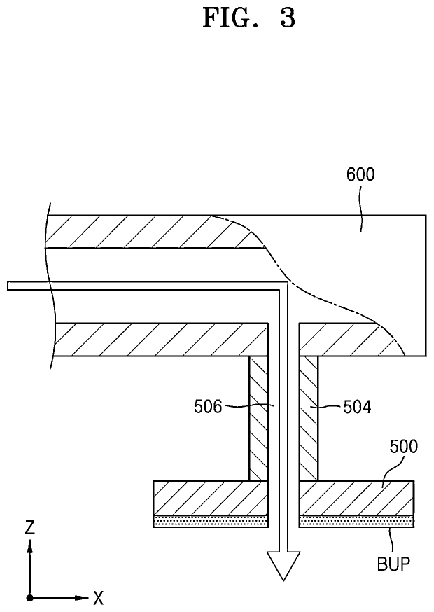

FIG. 2 is a schematic perspective view of the configuration of the buffing treatment module 200 of FIG. 1, and FIG. 3 is a schematic cross-sectional view of the internal structure of a buffing head of FIG. 2.

For example, the buffing treatment module 200 may include a buffing table 400 to support the substrate 120 (or a wafer), a buffing head 500 having a buffing pad BUP for providing buffing treatment on a treatment surface of the substrate 120, a buffing arm 600 for holding and supporting the buffing head 500, a liquid supply system 700 for supplying various treatment liquids, and a conditioning unit 800 for conditioning (dressing) the buffing pad BUP.

The buffing table 400 has a mechanism for holding and supporting the substrate 120. The mechanism herein is a vacuum adsorption type but may be any type. For example, the mechanism may be a clamp type that clamps front and back surfaces of the substrate 120 on at least one location on the periphery of the substrate 120, or may be a roller chuck type that holds and supports side surfaces of the substrate 120 on at least one location on the periphery of the substrate 120. The buffing table 400 herein holds and supports the substrate 120 such that a processing surface of the substrate 120 faces upward. For example, the buffing table 400 includes a wall 402 that extends from an upper surface of the buffing table 400. The buffing table 400 may be configured to rotate around a rotation axis A by a driving mechanism.

A rotatable shaft 504 is installed on the buffing arm 600, and the buffing pad BUP for buffing the substrate 120 is installed to face the buffing table 400. The buffing arm 600 is configured to rotate the buffing head 500 around a rotation axis B. The area of the buffing pad BUP may be less than that of the substrate 120 or the buffing table 400. To enable the buffing pad BUP to evenly buff the substrate 120, the buffing arm 600 may be configured to move the buffing head 500 in a radial direction of the substrate 120 as indicated by an arrow C.

The buffing arm 600 may be configured to move the buffing head 500 to a position where the buffing pad BUP faces the conditioning unit 800. The buffing head 500 may be configured to be vertically movable by an actuator in a direction approaching the buffing table 400 and in a direction away from the buffing table 400. Accordingly, the buffing pad BUP may be pressed against the substrate 120 with predetermined pressure. This configuration may be realized by expansion and contraction of the shaft 504 or by vertical movement of the buffing arm 600.

The liquid supply system 700 may be provided with a deionized water external nozzle 710 for supplying deionized water to the treatment surface of the substrate 120. The deionized water external nozzle 710 is connected to a deionized water supply source 714 through a deionized water pipe 712. An on-off valve 716 capable of opening and closing the deionized water pipe 712 is installed on the deionized water pipe 712. When controlling the opening and closing of the on-off valve 716, deionized water may be supplied to the treatment surface of the substrate 120 at a predetermined timing; however, the present inventive concept is not limited thereto, and the timing may be arbitrary.

The liquid supply system 700 is provided with a chemical liquid external nozzle 720 for supplying chemical liquid to the treatment surface of the substrate 120. The chemical liquid external nozzle 720 is connected to a chemical liquid supply source 724 through a chemical liquid pipe 722. An on-off valve 726 capable of opening and closing the chemical liquid pipe 722 is installed on the chemical liquid pipe 722. When controlling the opening and closing of the on-off valve 726, chemical liquid may be supplied to the treatment surface of the substrate 120 at a predetermined timing; however, the present inventive concept is not limited thereto, and the timing may be arbitrary.

The liquid supply system 700 is provided with a slurry external nozzle 730 for supplying slurry to the treatment surface of the substrate 120. The slurry external nozzle 730 is connected to a slurry source 734 through a slurry pipe 732. An on-off valve 736 capable of opening and closing the slurry pipe 732 is installed on the slurry pipe 732. When controlling the opening and closing of the on-off valve 736, slurry may be supplied to the treatment surface of the substrate 120 at a predetermined timing; however, the present inventive concept is not limited thereto, and the timing may be arbitrary.

The external nozzles 710, 720, and 730 herein all have fixed positions and supply deionized water, chemical liquid, or slurry toward predetermined fixed positions. These treatment liquids are supplied to positions where the treatment liquids are efficiently supplied to the buffing pad BUP by rotation of the substrate 120. The external nozzles 710, 720, and 730 may be configured to supply at least one type of treatment liquid among deionized water, chemical liquid, and slurry.

The buffing treatment module 200 may be configured to selectively supply a treatment liquid (e.g., deionized water, chemical liquid, or slurry) to the treatment surface of the substrate 120 through the buffing arm 600, the buffing head 500, and the buffing pad BUP. A branched deionized water pipe 712a branches off from the deionized water pipe 712 and branches off at a portion that is between the deionized water supply source 714 and the on-off valve 716.

In addition, a branched chemical liquid pipe 722a branches off from the chemical liquid pipe 722 and branches off at a portion that is between the chemical liquid supply source 724 and the on-off valve 726. A branched slurry pipe 732a branches off from the slurry pipe 732 and branches off at a portion that is between the slurry source 734 and the on-off valve 736.

The branched deionized water pipe 712a, the branched chemical liquid pipe 722a, and the branched slurry pipe 732a are joined to a liquid supply pipe 740. An on-off valve 718 capable of opening and closing the branched deionized water pipe 712a is installed on the branched deionized water pipe 712a. An on-off valve 728 capable of opening and closing the branched chemical liquid pipe 722a is installed on the branched chemical liquid pipe 722a.

An on-off valve 738 capable of opening and closing the branched slurry pipe 732a is installed on the branched slurry pipe 732a. The liquid supply pipe 740 communicates with the interior of the buffing arm 600, the central interior of the buffing head 500, and the central interior of the buffing pad BUP.

Specifically, as shown in FIG. 3, an internal supply line 506 is formed inside the buffing arm 600, the buffing head 500, and the buffing pad BUP, and the internal supply line 506 communicates with the liquid supply pipe 740. The internal supply line 506 is opened toward an upper surface (the treatment surface of the substrate 120) of the buffing table 400.

According to this configuration, during the buffing treatment, the treatment liquids supplied to a central portion of the buffing pad BUP through the internal supply line 506 may be evenly spread between the buffing pad BUP and the substrate 120 by the centrifugal force caused by the rotation of the buffing head 500 and the supply pressure of the treatment liquids.

When the treatment liquid is supplied to the substrate 120 from a nozzle that is installed outside the buffing head 500, the treatment liquid might not sufficiently spread to the central portion of the buffing pad BUP during high-speed rotation of the buffing table 400. This is due to the centrifugal force increasing due to the high-speed rotation.

In addition, when the buffing treatment is performed on the substrate 120 having a relatively large diameter (e.g., about 300 mm), a diameter of the buffing head 500 may be increased to, e.g., about 60 mm to about 150 mm, to efficiently perform the buffing treatment. In embodiments of the present inventive concept, the diameter of the buffing head 500 may be increased to about 134 mm. Therefore, when the treatment liquid is supplied from the outside of the buffing pad BUP, the treatment liquid might not sufficiently spread to the central portion of the buffing pad BUP.

In this case, the buffing treatment speed (e.g., polishing speed or cleaning speed) may be decreased. However, according to the configuration herein for supplying the treatment liquid from the internal supply line 506, the treatment liquid may be evenly spread between the buffing pad BUP and the substrate 120 as described above, thereby suppressing a decrease in the buffing treatment speed due to the insufficient treatment liquid. In addition, damage to the substrate 120 due to a shortage of treatment liquid may be prevented.

Only one opening of the internal supply line 506 is formed in the center of the buffing pad BUP herein, but a plurality of openings may be formed therein. For example, the internal supply line 506 may branch toward a plurality of dispersed openings through a water pool jacket structure formed within the buffing head 500.

The plurality of openings may be distributed so that their positions in the radial direction are different. When the opening and closing of the on-off valve 716, the on-off valve 726, and the on-off valve 736 are controlled, any one of deionized water, chemical liquid, slurry, or a mixed solution of any combination thereof may be supplied to the treatment surface of the substrate 120 at a predetermined timing; however, the present inventive concept is not limited thereto, and the timing may be arbitrary.

The buffing treatment module 200 is equipped with two systems of treatment liquid supply means: the external nozzles 710, 720, and 730; and the internal supply line 506. One or both of these two systems may be optionally used. A conditioning unit 800 is a member for conditioning (dressing) the surface of the buffing pad BUP. The conditioning unit 800 is positioned outside the buffing table 400. The conditioning unit 800 may move above the buffing table 400 and below the buffing head 500 to perform conditioning of the buffing pad BUP. In this case, the conditioning is performed after the treated substrate 120 is unloaded.

The conditioning unit 800 includes a conditioning table 810 and a conditioner 820 installed on the conditioning table 810. The conditioning table 810 is configured to rotate about a rotation axis D by a driving mechanism (e.g., an actuator). The conditioner 820 may include, for example, a diamond conditioner, a brush conditioner, or a combination thereof.

In embodiments of the present inventive concept, after the buffing pad BUP is transferred to the conditioning unit 800, deionized water or chemical liquid may be supplied to a center portion or a peripheral portion (or edge portion) of the buffing pad BUP while the buffing pad BUP is rotated to condition the buffing pad BUP.

When the buffing treatment module 200 performs conditioning of the buffing pad BUP, the buffing arm 600 is rotated until the buffing pad BUP is at a position facing the conditioner 820. The buffing treatment module 200 performs conditioning of the buffing pad BUP by rotating the conditioning table 810 around the rotation axis D, rotating the buffing head 500, and pressing the buffing pad BUP against the conditioner 820. Such a conditioning operation may be performed, for example, while the buffed substrate 120 is replaced with another substrate 120 to be buffed next.

The buffing treatment module 200 may perform the buffing treatment of the substrate 120 by rotating the buffing table 400 around the rotation axis A while supplying the treatment liquid through at least one of the external nozzles 710, 720, and 730 and the internal supply line 506, pressing the buffing pad BUP against the treatment surface of the substrate 120, and rotating the buffing head 500 around the rotation axis B while moving the same in the direction of the arrow C.

The relative movement between the buffing table 400 and the buffing head 500 during the buffing treatment is not limited thereto and may be realized by at least one of rotational movement, translational movement, circular movement, reciprocating movement, scroll movement, and/or angular rotation movement (movement that rotates only by a certain angle less than 360 degrees).

The buffing treatment includes at least one of buff polishing treatment and buff cleaning treatment. The buffing polishing treatment is a treatment of polishing and removing the treatment surface of the substrate 120 by bringing the buffed pad BUP into contact with the substrate 120, relatively moving the substrate 120 and the buffing pad BUP, and applying the slurry between the substrate 120 and the buffing pad BUP.

The buffing polishing treatment is a final polishing that is performed after main polishing for the purpose of flattening the recessed surface of the substrate 120 or removing excess films formed on the surface thereof other than the inside of trenches or vias. The amount of removal processing of buffing polishing may be, for example, about several nanometers to about tens of nanometers. As the buffing pad BUP, a pad including, e.g., polyvinyl alcohol (PVA), a pad obtained by laminating foamed polyurethane and nonwoven fabric, or a suede-like porous polyurethane non-fibrous pad may be used.

The buffing polishing treatment is a treatment capable of applying a strong physical force to the substrate 120. Through the buffing polishing treatment, it is possible to remove the surface layer with damage such as scratches or foreign substances attached thereto, additionally remove areas that could not be removed by main polishing, or improve morphology such as recessed micro-areas and film thickness distribution over the entire substrate after main polishing.

The buffing cleaning treatment is a finishing treatment that removes foreign substances or particles from the surface of the substrate 120 or modifies the treatment surface thereof by bringing the buffing pad BUP into contact with the substrate 120, relatively moving the substrate 120 and the buffing pad BUP, and applying a cleaning treatment liquid (chemical liquid, deionized water, or a mixture thereof) between the substrate 120 and the buffing pad BUP. The buffing cleaning treatment is a treatment capable of applying a strong physical force to the substrate 120. According to the buffing cleaning treatment, highly sticky foreign substances, etc. may be efficiently cleaned and removed.

By employing this buffing treatment as a post-treatment of the CMP-treated substrate 120, it is possible to perform final polishing while suppressing damage or defects to the substrate 120, or remove damage caused by the CMP treatment or efficiently clean and remove highly sticky foreign substances. In addition, as the substrate 120 becomes larger in diameter and semiconductor devices become more highly integrated, the buffing pad BUP that is capable of suppressing the occurrence of scratches on the substrate 120 and removing small particles, for example, particles with a diameter of several nanometers or less, during the buffing treatment, such as buffing polishing treatment or buffing cleaning treatment, is desirable.

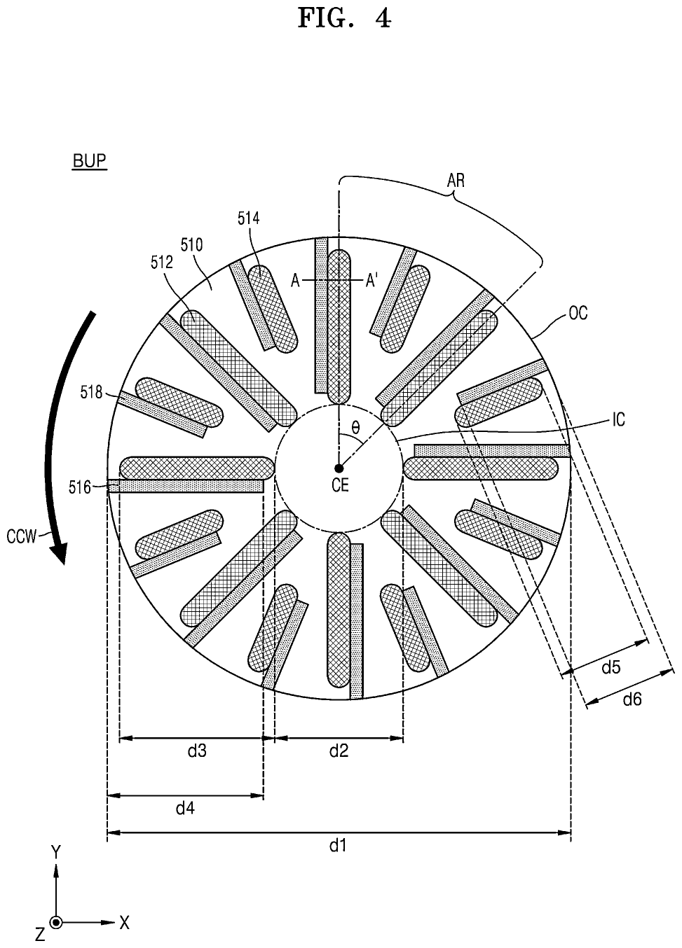

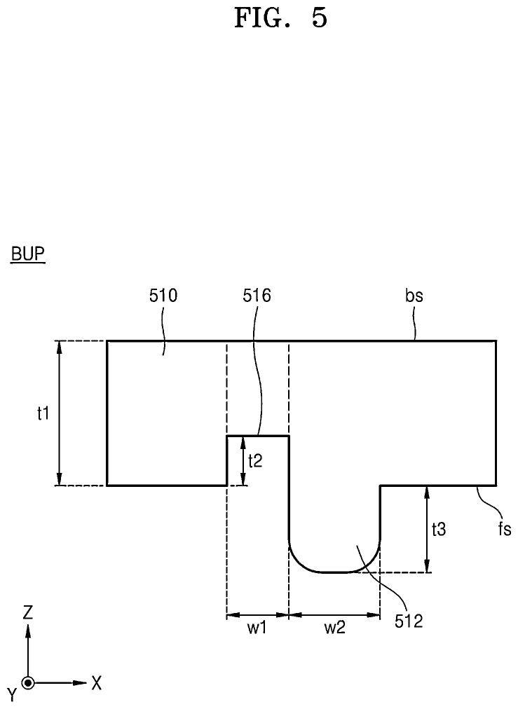

FIG. 4 is a plan view of a buffing pad included in a buffing treatment module according to an embodiment of the present inventive concept, and FIG. 5 is a cross-sectional view taken along line A-A′ of FIG. 4.

For example, the buffing pad BUP of FIG. 4 and FIG. 5 may be included in the buffing treatment module 200 of FIGS. 1 and 2. The buffing treatment module (200 in FIGS. 1 and 2) may include the buffing table (400 in FIG. 2) capable of supporting and rotating the substrate (120 in FIG. 2), the buffing head (500 in FIGS. 2 and 3) positioned on the buffing table (400 in FIG. 2) and rotatable, and the buffing pad BUP that is attached to the lower part of the buffing head (500 in FIGS. 2 and 3) and rotates while in contact with the substrate (120 in FIG. 2) to perform the buffing treatment on the substrate (120 in FIG. 2).

The buffing pad BUP may rotate according to the rotation of the buffing head (500 in FIGS. 2 and 3). In FIG. 4, the buffing pad BUP rotates counterclockwise CCW; however, the present inventive concept is not limited thereto.

The buffing pad BUP may include a circular base unit 510. The circular base unit 510 may include a back surface bs and a front surface fs. The back surface bs may be installed on the buffing head (500 in FIGS. 2 and 3). The base unit 510 may have a thickness t1. In embodiments of the present inventive concept, t1 may be about 2 mm to about 10 mm.

The base unit 510 may have an outer circle OC and an inner circle IC that is located in the outer circle OC. The inner circle IC may be a virtual inner circle that is located inside the base unit 510. The outer circle OC of the base unit 510 may have a diameter d1. In embodiments of the present inventive concept, the diameter d1 may be about 60 mm to about 150 mm. In embodiments of the present inventive concept, diameter d1 may be about 67 mm. In embodiments of the present inventive concept, diameter d1 may be about 134 mm.

The diameter d1 of the outer circle OC of the base unit 510 may be less than the diameter (e.g., about 300 mm) of the substrate (120 of FIG. 2). The inner circle IC may have a diameter d2. In embodiments of the present inventive concept, the diameter d2 may be about 10 mm to about 30 mm. For convenience of description, it is described herein that the inner circle IC is present in the base unit 510, but components outside the inner circle IC may also be arranged inside the inner circle IC.

The buffing pad BUP may include a plurality of protrusion units 512 and 514 protruding from a surface of the base unit 510 within the circular base unit 510. The protrusion units 512 and 514 may be provided to facilitate polishing of the substrate (120 in FIG. 2) during the buffing treatment, especially the buffing polishing treatment.

The protrusion units 512 and 514 may be spaced apart from each other in a circumferential direction of the base unit 510. Each of the protrusion units 512 and 514 may have a thickness t3 from the front surface fs of the base unit 510. In embodiments of the present inventive concept, the thickness t3 may be about 1 mm to about 5 mm. The protrusion units 512 and 514 may have a width w2. In embodiments of the present inventive concept, the width w2 may be about 2 mm to about 4 mm.

The protrusion units 512 and 514 may include a plurality of long protrusion units 512 with a long length in a radial direction of the base unit 510, and a plurality of short protrusion units 514 with a short length in the radial direction of the base unit 510. The long protrusion units 512 and the short protrusion units 514 may be alternately arranged in the circumferential direction of the base unit 510. For example, the plurality of short protrusion units 514 may have a length that is smaller than a length of the plurality of long protrusion units 512.

The long protrusion units 512 may be in contact with the inner circle IC. For example, the long protrusion units 512 may extend to the boundary of the inner circle IC. The long protrusion units 512 may have a length d3 in the radial direction of the base unit 510. In embodiments, the length d3 may be about 20 mm to about 30 mm.

The short protrusion units 514 might not be in contact with the inner circle IC. The short protrusion units 514 may have a length d5 in the radial direction of the base unit 510. In embodiments of the present inventive concept, the length d5 may be about 10 mm to about 20 mm. In embodiments of the present inventive concept, the length d5 may be about 15 mm. The length d5 of the short protrusion units 514 may be less than a length d4 of long trench units 516 in the radial direction of the base unit 510.

The buffing pad BUP may include a plurality of trench units 516 and 518 that are positioned adjacent to the protrusion units 512 and 514 and extending from a center portion to an edge portion of the base unit 510. The trench units 516 and 518 may be provided to easily discharge treatment liquids such as deionized water, chemical liquid, and slurry supplied to the substrate (120 in FIG. 2) during the buffing treatment, especially the buffing cleaning treatment. The trench units 516 and 518 may extend from the inside of the base unit 510 to the outer circle OC.

The plurality of trench units 516 and 518 are spaced apart from each other in the circumferential direction of the base unit 510. The trench units 516 and 518 may be arranged at a depth t2 from the front surface fs of the base unit 510. In embodiments of the present inventive concept, depth t2 may be about 1 mm to about 5 mm. The trench units 516 and 518 may have a width w1. In embodiments of the present inventive concept, the width w1 may be about 1 mm to about 3 mm.

The trench units 516 and 518 may be in direct contact with the protrusion units 512 and 514. For example, the trench units 516 and 518 may be adjacent to the protrusion units 512 and 514. The trench units 516 and 518 extend from the inner circle IC to the outer circle OC. For example, the trench units 516 and 518 may be arranged at front sides of the protrusion units 512 and 514 according to the rotation direction of the buffing head (500 in FIGS. 2 and 3), that is, the rotation direction of the buffing pad BUP. For example, the front sides of the protrusion units 512 and 514 may face the rotation direction of the buffing head. In FIGS. 4 and 5, as the buffing pad BUP rotates counterclockwise CCW, the trench units 516 and 518 may be arranged on the left side of the protrusion units 512 and 514.

The trench units 516 and 518 may include a plurality of long trench units 516 with a long length in the radial direction of the base unit 510 and a plurality of short trench units 518 with a short length in the radial direction of the base unit 510. The long trench units 516 may be in contact with the long protrusion units 512.

The long trench units 516 may have a length d4 in the radial direction of the base unit 510. In embodiments of the present inventive concept, the length d4 may be about 20 mm to about 30 mm. The short trench units 518 may have a length d6 in the radial direction of the base unit 510. In embodiments of the present inventive concept, the length d6 may be about 10 mm to about 15 mm. The short trench units 518 may be in contact with the short protrusion units 514.

The buffing pad BUP may include the base unit 510 having a center point CE. The base unit 510 may include a circular sector AR based on the center point CE. The base unit 510 herein may include eight circular sectors AR each having a central angle θ of about 45 degrees. One circular sector AR may include one long protrusion unit 512, one short protrusion unit 514, one long trench unit 516, and one short trench unit 518 based on area.

The buffing pad BUP configured in this manner may include the protrusion units 512 and 514 and the trench units 516 and 518 in the base unit 510. Among the base unit 510, the protrusion units 512 and 514, and the trench units 516 and 518, the base unit 510 may have the largest area.

In addition, according to the arrangement of the protrusion units 512 and 514 and the trench units 516 and 518 in the base unit 510, the buffing pad BUP may facilitate the buffing treatment and may easily discharge the treatment liquids such as deionized water, chemical liquid, and slurry during the buffing treatment. Accordingly, using the buffing pad BUP according to embodiments of the present inventive concept, it is possible to suppress the occurrence of scratches on the substrate (120 in FIG. 2) during the buffing treatment and to easily remove small particles, for example, particles having a small diameter of several nm or less.

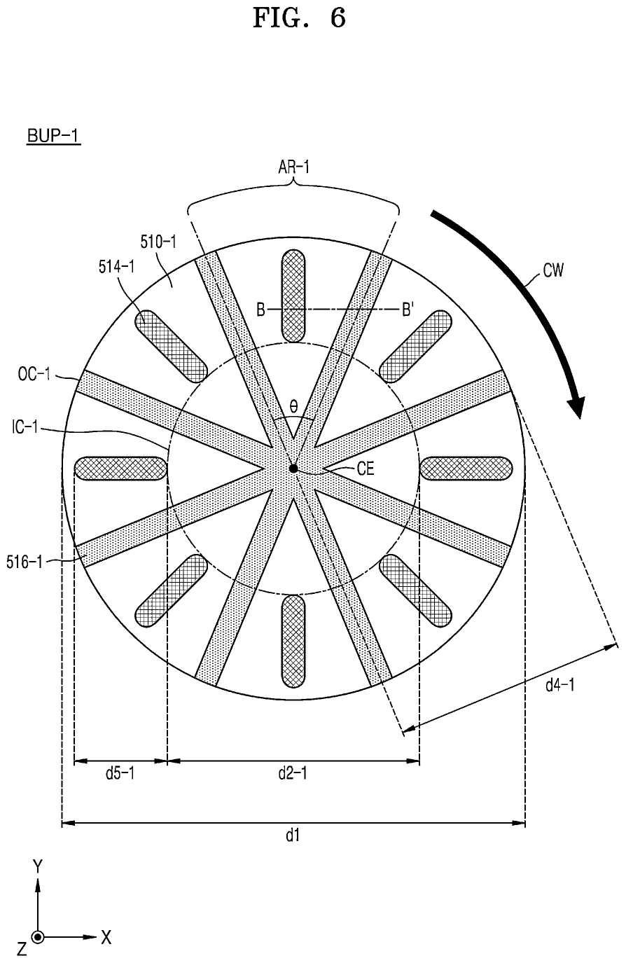

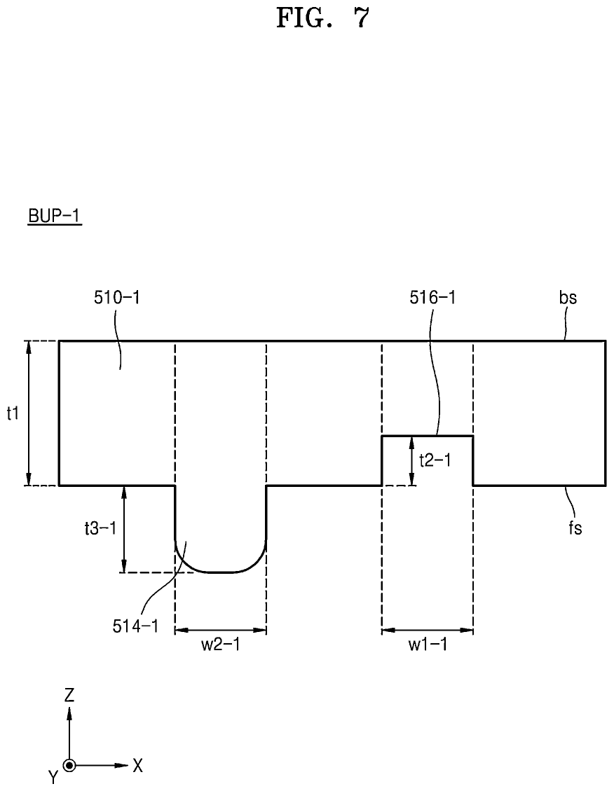

FIG. 6 is a plan view of a buffing pad included in a buffing treatment module according to an embodiment of the present inventive concept, and FIG. 7 is a cross-sectional view taken along line B-B′ of FIG. 6.

For example, a buffing pad BUP-1 may be substantially the same as the buffing pad BUP of FIGS. 4 and 5, except for the configuration of protrusion units 514-1 and trench units 516-1. In FIGS. 6 and 7, the same descriptions as those given with reference to FIGS. 4 and 5 are briefly given or omitted.

The buffing pad BUP-1 may be included in the buffing treatment module 200 of FIGS. 1 and 2. The buffing treatment module (200 of FIGS. 1 and 2) may include the buffing pad BUP-1 that performs the buffing treatment on the substrate (120 of FIG. 2) by rotating while in contact with the substrate (120 in FIG. 2). The buffing pad BUP-1 may rotate according to the rotation of the buffing head (500 in FIGS. 2 and 3). In FIG. 6, the buffing pad BUP-1 rotates clockwise CW.

The buffing pad BUP-1 may include a circular base unit 510-1. The circular base unit 510-1 may include a back surface bs and a front surface fs. The back surface bs may be installed on the buffing head (500 in FIGS. 2 and 3). The base unit 510-1 may have a thickness t1. In embodiments of the present inventive concept, t1 may be about 5 mm to about 10 mm.

The base unit 510-1 may have an outer circle OC-1 and an inner circle IC-1 that is located in the outer circle OC-1. The inner circle IC-1 may be a virtual inner circle located inside the base unit 510-1. The outer circle OC-1 of the base unit 510-1 may have a diameter d1. In embodiments of the present inventive concept, the diameter d1 may be about 60 mm to about 150 mm. In embodiments of the present inventive concept, diameter d1 may be about 67 mm.

The diameter of the outer circle OC-1 of the base unit 510-1, that is, the diameter d1, may be less than the diameter of the substrate (120 of FIG. 2). The inner circle IC-1 may have a diameter d2-1. In embodiments of the present inventive concept, the diameter d2-1 may be about 20 mm to about 40 mm.

The buffing pad BUP-1 may include a plurality of protrusion units 514-1 that protrude from the surface of the base unit 510-1 within the circular base unit 510-1. The protrusion units 514-1 may be provided to facilitate polishing of the substrate (120 in FIG. 2) during the buffing treatment, especially the buffing polishing treatment.

The protrusion units 514-1 may be spaced apart from each other in a circumferential direction of the base unit 510-1. Each of the protrusion units 514-1 may have a thickness t3-1 from the front surface fs of the base unit 510-1. In embodiments of the present inventive concept, the thickness t3-1 may be about 1 mm to about 5 mm. The protrusion units 514-1 may have a width w2-1. In embodiments of the present inventive concept, the width w2-1 may be about 2 mm to about 4 mm.

The protrusion units 514-1 may be short protrusion units with a short length in a radial direction of the base unit 510-1. The protrusion units 514-1 may contact the inner circle IC-1. For example, the protrusion units 514-1 may extend to the boundary of the inner circle IC-1. The protrusion units 514-1 may have a length d5-1 in the radial direction of the base unit 510-1. In embodiments of the present inventive concept, the length d5-1 may be about 10 mm to about 15 mm. The length d5-1 of the protrusion units 514-1 may be less than the length d4-1 of the trench units 516-1 in the radial direction of the base unit 510-1.

The buffing pad BUP-1 may include the plurality of trench units 516-1 positioned adjacent to the protrusion units 514-1 and extending from a center portion to an edge portion of the base unit 510-1. The trench units 516-1 may be provided to easily discharge treatment liquids such as deionized water, chemical liquid, and slurry supplied to the substrate (120 in FIG. 2) during the buffing treatment, especially the buffing cleaning treatment. The trench units 516-1 may extend from the inside of the base unit 510-1, particularly from a center point CE thereof, to the outer circle OC-1.

The trench units 516-1 are spaced apart from each other in the circumferential direction of the base unit 510-1. The trench units 516-1 may be arranged at a depth t2-1 from the front surface fs of the base unit 510-1. In embodiments of the present inventive concept, the depth t2-1 may be about 1 mm to about 5 mm. The trench units 516-1 may have a width w1-1. In embodiments of the present inventive concept, the width w1-1 may be about 2 mm to about 4 mm.

The width of the trench units 516-1 at the inner circle IC-1 of the base unit 510-1 herein may be the same as the width of the trench units 516-1 at the edge portion of the base unit 510-1 in the circumferential direction of the base unit 510-1. In embodiments of the present inventive concept, the width of the trench units 516-1 at the inner circle IC-1 of the base unit 510-1 may be less than the width of the trench units 616-1 at the edge portion of the base unit 510-1 in the circumferential direction.

The trench units 516-1 may be spaced apart from the protrusion units 514-1. The trench units 516-1 extend from the center portion of the base unit 510-1 to the outer circle OC-1.

The trench units 516-1 may be arranged at front ends of the protrusion units 514-1 according to the rotation direction of the buffing head (500 in FIGS. 2 and 3), that is, the rotation direction of the buffing pad BUP-1. In FIGS. 6 and 7, as the buffing pad BUP-1 rotates clockwise CW, the trench units 516-1 may be arranged on the right side of the protrusion units 514-1. For example, each protrusion unit 514-1 may be disposed between neighboring trench units 516-1.

The trench units 516-1 may be a plurality of long trench units with a long length in the radial direction of the base unit 510-1. The trench units 516-1 may be spaced apart from the protrusion units 514-1 in the circumferential direction of the base unit 510-1. The trench units 516-1 may have a length d4-1 in the radial direction of the base unit 510-1. In embodiments of the present inventive concept, the length d4-1 may be about 30 mm to about 50 mm.

The buffing pad BUP-1 may include the base unit 510-1 having the center point CE. The base unit 510-1 may include a circular sector AR-1 based on the center point CE. The base unit 510-1 herein may include eight circular sectors AR-1 each having a central angle θ of 45 degrees. One circular sector AR-1 may include one protrusion unit 514-1 and one trench unit 516-1 based on area.

The buffing pad BUP-1 configured in this manner may include the protrusion units 514-1 and the trench units 516-1 within the base unit 510-1. Among the base unit 510-1, the protrusion units 514-1, and the trench units 516-1, the base unit 510-1 may have the largest area.

In addition, according to the arrangement of the protrusion units 514-1 and the trench units 516-1 in the base unit 510-1, the buffing pad BUP-1 may facilitate the buffing treatment and may easily discharge the treatment liquids such as deionized water, chemical liquid, and slurry during the buffing treatment. Accordingly, using the buffing pad BUP-1 according to embodiments of the present inventive concept, it is possible to suppress the occurrence of scratches on the substrate (120 in FIG. 2) during the buffing treatment and to easily remove small particles.

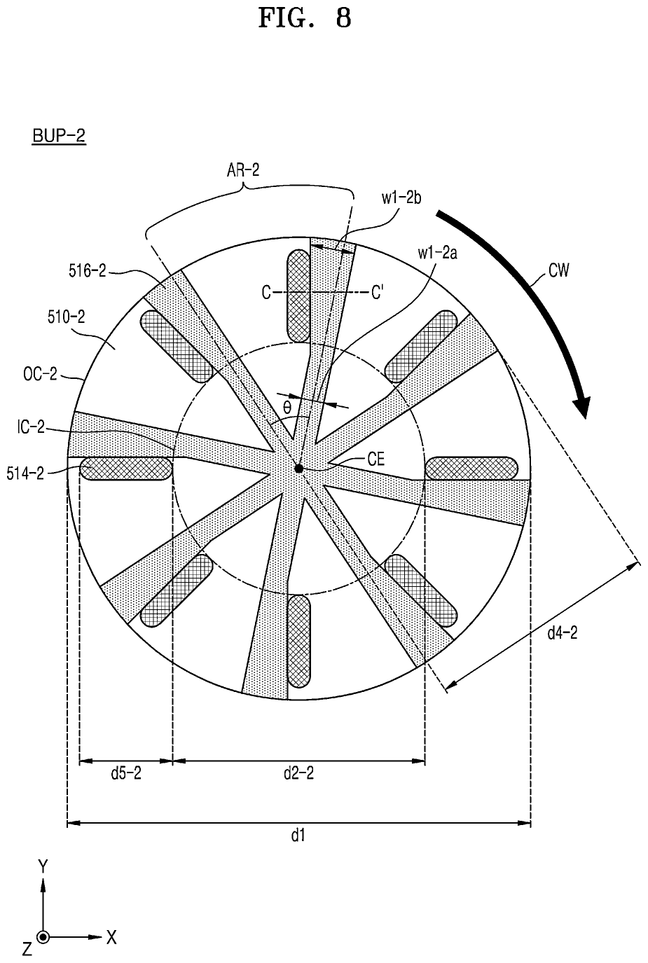

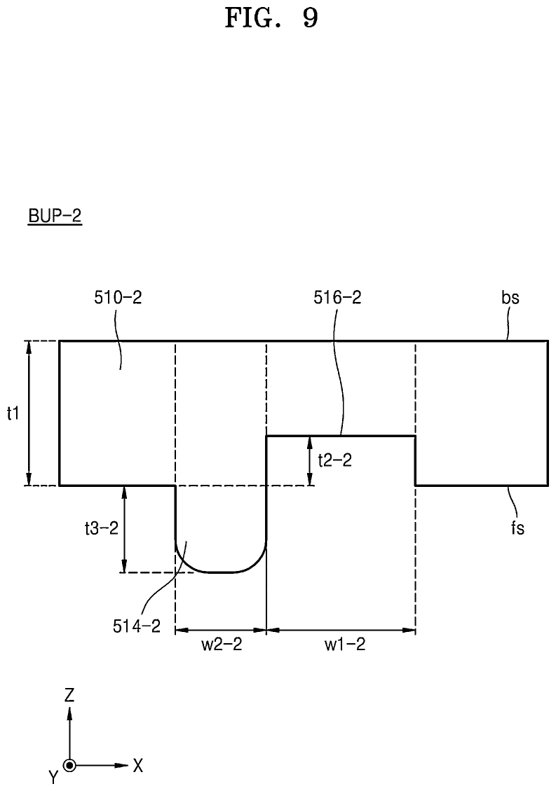

FIG. 8 is a plan view of a buffing pad included in a buffing treatment module according to an embodiment of the present inventive concept, and FIG. 9 is a cross-sectional view taken along line C-C′ of FIG. 8.

For example, a buffing pad BUP-2 may be substantially the same as the buffing pad BUP of FIGS. 4 and 5, except for the configuration of protrusion units 514-2 and trench units 516-2. In FIGS. 8 and 9, the same descriptions as those given with reference to FIGS. 4 and 5 are briefly given or omitted.

The buffing pad BUP-2 may be included in the buffing treatment module 200 of FIGS. 1 and 2. The buffing treatment module (200 of FIGS. 1 and 2) may include the buffing pad BUP-2 that performs the buffing treatment on the substrate (120 of FIG. 2) by rotating while in contact with the substrate (120 in FIG. 2). The buffing pad BUP-2 may rotate according to the rotation of the buffing head (500 in FIGS. 2 and 3). In FIG. 8, the buffing pad BUP-2 rotates clockwise CW.

The buffing pad BUP-2 may include a circular base unit 510-2. The circular base unit 510-2 may include a back surface bs and a front surface fs. The back surface bs may be installed on the buffing head (500 in FIGS. 2 and 3). The base unit 510-2 may have a thickness t1. In embodiments of the present inventive concept, the thickness t1 may be about 5 mm to about 10 mm.

The base unit 510-2 may have an outer circle OC-2 and an inner circle IC-2 that is located within the outer circle OC-2. The inner circle IC-2 may be a virtual inner circle that is located inside the base unit 510-2. The outer circle OC-2 of the base unit 510-2 may have a diameter d1. In embodiments of the present inventive concept, the diameter d1 may be about 60 mm to about 150 mm. In embodiments of the present inventive concept, the diameter d1 may be about 67 mm. The diameter of the outer circle OC-2 of the base unit 510-2, that is, the diameter d1, may be less than the diameter of the substrate (120 of FIG. 2). The inner circle IC-2 may have a diameter d2-2. In embodiments of the present inventive concept, d2-2 may be about 20 mm to about 40 mm.

The buffing pad BUP-2 may include a plurality of protrusion units 514-2 that protrude from the surface of the base unit 510-2. The protrusion units 514-2 may be provided to facilitate polishing of the substrate (120 in FIG. 2) during the buffing treatment, especially the buffing polishing treatment.

The protrusion units 514-2 may be spaced apart from each other in a circumferential direction of the base unit 510-2. Each of the protrusion units 514-2 may have a thickness t3-2 from the front surface fs of the base unit 510-2. In embodiments of the present inventive concept, the thickness t3-2 may be about 1 mm to about 5 mm. The protrusion units 514-2 may have a width w2-2. In embodiments of the present inventive concept, the width w2-2 may be about 2 mm to about 4 mm.

The protrusion units 514-2 may be short protrusion units with a short length in a radial direction of the base unit 510-2. The protrusion units 514-2 may contact the inner circle IC-2. For example, the protrusion units 514-2 may extend to a boundary of the inner circle IC-2. The protrusion units 514-2 may have a length d5-2 in the radial direction of the base unit 510-2. In embodiments of the present inventive concept, the length d5-2 may be about 10 mm to about 15 mm. The length d5-2 of the protrusion units 514-2 may be less than the length d4-2 of the trench units 516-2 in the radial direction of the base unit 510-2.

The buffing pad BUP-2 may include the plurality of trench units 516-2 that are positioned adjacent to the protrusion units 514-2 and extending from the center portion to the edge portion of the base unit 510-2. The trench units 516-2 may be provided to easily discharge treatment liquids such as deionized water, chemical liquid, and slurry supplied to the substrate (120 in FIG. 2) during the buffing treatment, especially the buffing cleaning treatment. The trench units 516-2 may extend from the inside of the base unit 510-2, particularly from the center point CE thereof, to the outer circle OC-2.

The trench units 516-2 are spaced apart from each other in the circumferential direction of the base unit 510-2. The trench units 516-2 may have a depth t2-2 from the front surface fs of the base unit 510-2. In embodiments of the present inventive concept, the depth t2-2 may be about 1 mm to about 5 mm. The trench units 516-2 may have a width w1-2. In embodiments of the present inventive concept, the width w1-2 may be about 3 mm to about 6 mm.

The width of the trench units 516-2 at the edge portion of the base unit 510-2 may be greater than the width of the trench units 516-2 at the inner circle IC-2 of the base unit 510-2 in the circumferential direction of the base unit 510-2. The width of the trench units 516-2 may gradually increase in the radial direction of the base unit 510-2. The width of the trench units 516-2 may gradually increase from the center portion of the base unit 510-2 to the outer circle OC-2.

For example, the trench units 516-2 may have a width w1-2a within the inner circle IC-2, and may have a width w1-2b outside the inner circle IC-2 and near the outer circle OC-2. The width w1-2b may be greater than the width w1-2a. When the width w1-2b is greater than the width w1-2a, treatment liquids such as deionized water, chemical liquid, and slurry supplied to the substrate (120 in FIG. 2) during the buffing treatment, especially the buffing cleaning treatment, may be easily discharged.

It is shown herein that the width of the trench units 516-2 at the edge portion of the base unit 510-2 may be greater than the width of the trench units 516-2 at the inner circle IC-2 of the base unit 510-2 in the circumferential direction of the base unit 510-2. However, the width of the trench units 516-2 at the edge portion of the base unit 510-2 may be less than the width of the trench units 516-2 at the inner circle IC-2 of the base unit 510-2 in the circumferential direction of the base unit 510-2.

The trench units 516-2 may be in contact with the protrusion units 514-2 in the circumferential direction of the base unit 510-2. The trench units 516-2 extend from the central portion of the base unit 510-2 to the outer circle OC-2.

The trench units 516-2 may be arranged at front ends of the protrusion units 514-2 according to the rotation direction of the buffing head (500 in FIGS. 2 and 3), that is, the rotation direction of the buffing pad BUP-2. In FIGS. 8 and 9, as the buffing pad BUP-2 rotates clockwise CW, the trench units 516-2 may be arranged on the right side of the protrusion units 514-2.

The trench units 516-2 may be a plurality of long trench units with a long length in the radial direction of the base unit 510-2. The trench units 516-2 may have a length d4-2 in the radial direction of the base unit 510-2. The buffing pad BUP-2 may include the base unit 510-2 having the center point CE.

The base unit 510-2 may include a circular sector AR-2 based on the center point CE. The base unit 510-2 herein may include eight circular sectors AR-2 each having a central angle θ of 45 degrees. One circular sector AR-2 may include one protrusion unit 514-2 and one trench unit 516-2 based on area.

The buffing pad BUP-2 may include the protrusion units 514-2 and the trench units 516-2 within the base unit 510-2. Among the base unit 510-2, the protrusion units 514-2, and the trench units 516-2, the base unit 510-2 may have the largest area.

In addition, according to the arrangement of the protrusion units 514-2 and the trench units 516-2 in the base unit 510-2, the buffing pad BUP-2 may facilitate the buffing treatment and may easily discharge the treatment liquids such as deionized water, chemical liquid, and slurry during the buffing treatment. Accordingly, using the buffing pad BUP-2 of the inventive concept, it is possible to suppress the occurrence of scratches on the substrate (120 in FIG. 2) during the buffing treatment and to easily remove small particles.

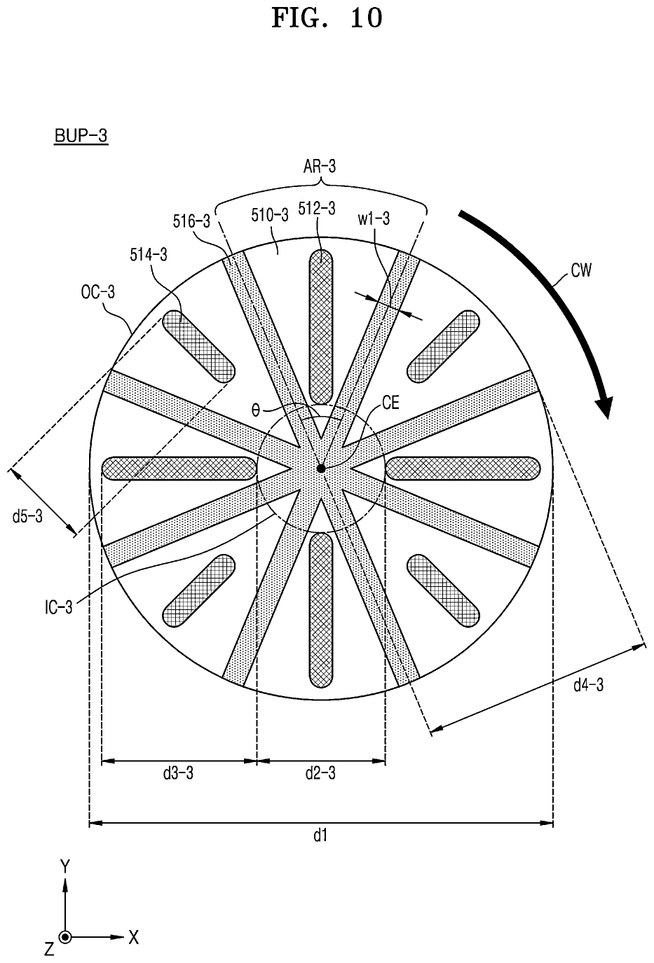

FIG. 10 is a plan view of a buffing pad included in a buffing treatment module according to an embodiment of the present inventive concept.

Specifically, a buffing pad BUP-3 may be substantially identical to the buffing pad BUP of FIGS. 4 and 5 except for the configuration of protrusion units 512-3 and 514-3 and trench units 516-3. In FIG. 10, the same descriptions as those given with reference to FIGS. 4 and 5 are briefly given or omitted.

The buffing pad BUP-3 may be included in the buffing treatment module 200 of FIGS. 1 and 2. The buffing treatment module (200 of FIGS. 1 and 2) may include the buffing pad BUP-3 that performs the buffing treatment on the substrate (120 of FIG. 2) by rotating while in contact with the substrate (120 in FIG. 2). The buffing pad BUP-3 may rotate according to the rotation of the buffing head (500 in FIGS. 2 and 3). In FIG. 10, the buffing pad BUP-3 rotates clockwise CW.

The buffing pad BUP-3 may include a circular base unit 510-3. The base unit 510-3 may have an outer circle OC-3 and an inner circle IC-3 that is located within the outer circle OC-3. The inner circle IC-3 may be a virtual inner circle located inside the base unit 510-3.

The outer circle OC-3 of the base unit 510-3 may have a diameter d1. In embodiments of the present inventive concept, the diameter d1 may be about 60 mm to about 150 mm. In embodiments of the present inventive concept, the diameter d1 may be about 67 mm. The diameter of the outer circle OC-3 of the base unit 510-3, that is, the diameter d1, may be less than the diameter of the substrate (120 of FIG. 2). The inner circle IC-3 may have a diameter d2-3. In embodiments of the present inventive concept, the diameter d2-3 may be about 10 mm to about 30 mm.

The buffing pad BUP-3 may include a plurality of protrusion units 512-3 and 514-3 that protrude from the surface of the base unit 510-3 within the circular base unit 510-3. The protrusion units 512-3 and 514-3 may be provided to facilitate polishing of the substrate (120 in FIG. 2) during the buffing treatment, especially the buffing polishing treatment.

The protrusion units 512-3 and 514-3 may be spaced apart from each other in a circumferential direction of the base unit 510-3. The protrusion units 512-3 and 514-3 may include long protrusion units 512-3, which has a long length, and short protrusion units 514-3, which has with a short length, in a radial direction of the base unit 510-3. The long protrusion units 512-3 and the short protrusion units 514-3 may be alternately arranged in the circumferential direction of the base unit 510-3.

The long protrusion units 512-3 may contact the inner circle IC-3. For example, the long protrusion units 512-3 may contact a boundary of the inner circle IC-3. The short protrusion units 514-3 might not contact the inner circle IC-3. The long protrusion units 512-3 may have a length d3-3 in the radial direction of the base unit 510-3. In embodiments of the present inventive concept, the length d3-3 may be about 20 mm to about 30 mm. The short protrusion units 514-3 may have a length d5-3 in the radial direction of the base unit 510-3. In embodiments of the present inventive concept, the length d5-3 may be about 10 mm to about 15 mm. The lengths d3-3 and d5-3 of the protrusion units 512-3 and 514-3 may be less than the length d4-3 of the trench units 516-3 in the radial direction of the base unit 510-3.

The buffing pad BUP-3 may include the plurality of trench units 516-3 that are positioned adjacent to the protrusion units 512-3 and 514-3 and extending from the center portion to the edge portion of the base unit 510-3. The trench units 516-3 may be provided to easily discharge treatment liquids such as deionized water, chemical liquid, and slurry supplied to the substrate (120 in FIG. 2) during the buffing treatment, especially the buffing cleaning treatment. The trench units 516-3 may extend from the inside of the base unit 510-3, particularly from the center point CE thereof, to the outer circle OC-3.

The trench units 516-3 are spaced apart from each other in the circumferential direction of the base unit 510-3. The trench units 516-3 may have a width w1-3. In embodiments, the width w1-3 may be about 2 mm to about 4 mm. The trench units 516-3 may be arranged to have a substantially uniform width in the radial direction of the base unit 510-3.

The trench units 516-3 may be spaced apart from the protrusion units 512-3 and 514-3. For example, a trench unit 516-3 may be disposed between a long protrusion unit 512-3 and a short protrusion unit 514-3. The trench units 516-3 extend from the central portion of the base unit 510-3 to the outer circle OC-3. The trench units 516-3 may be arranged at front ends of the protrusion units 512-3 and 514-3 according to the rotation direction of the buffing head (500 in FIGS. 2 and 3), that is, the rotation direction of the buffing pad BUP-3. In FIG. 10, as the buffing pad BUP-3 rotates clockwise CW, the trench units 516-3 may be arranged on the right side of the protrusion units 512-3 and 514-3.

The trench units 516-3 may be a plurality of long trench units with a long length in the radial direction of the base unit 510-3. The trench units 516-3 may be spaced apart from the protrusion units 512-3 and 514-3 in the circumferential direction of the base unit 510-3. The trench units 516-3 may have a length d4-3 in the radial direction of the base unit 510-3. In embodiments of the present inventive concept, length d4-3 may be about 30 mm to about 50 mm.

The buffing pad BUP-3 may include the base unit 510-3 having the center point CE. The base unit 510-3 may include a circular sector AR-3 based on the center point CE. The base unit 510-3 herein may include eight circular sectors AR-3 each having a central angle θ of 45 degrees. One circular sector AR-3 may include one of the long protrusion unit 512-3 or the short protrusion unit 514-3, and at least one trench unit 516-3 based on area.

The buffing pad BUP-3 configured in this manner may include the protrusion units 512-3 and 514-3 and the trench units 516-3 within the base unit 510-3. Among the base unit 510-3, the protrusion units 512-3 and 514-3, and the trench units 516-3, the base unit 510-3 may have the largest area.

In addition, according to the arrangement of the protrusion units 512-3 and 514-3 and the trench units 516-3 in the base unit 510-3, the buffing pad BUP-3 may facilitate the buffing treatment and may easily discharge the treatment liquids such as deionized water, chemical liquid, and slurry during the buffing treatment. Accordingly, using the buffing pad BUP-3 according to an embodiment of the present inventive concept, it is possible to suppress the occurrence of scratches on the substrate (120 in FIG. 2) during the buffing treatment and to easily remove small particles.

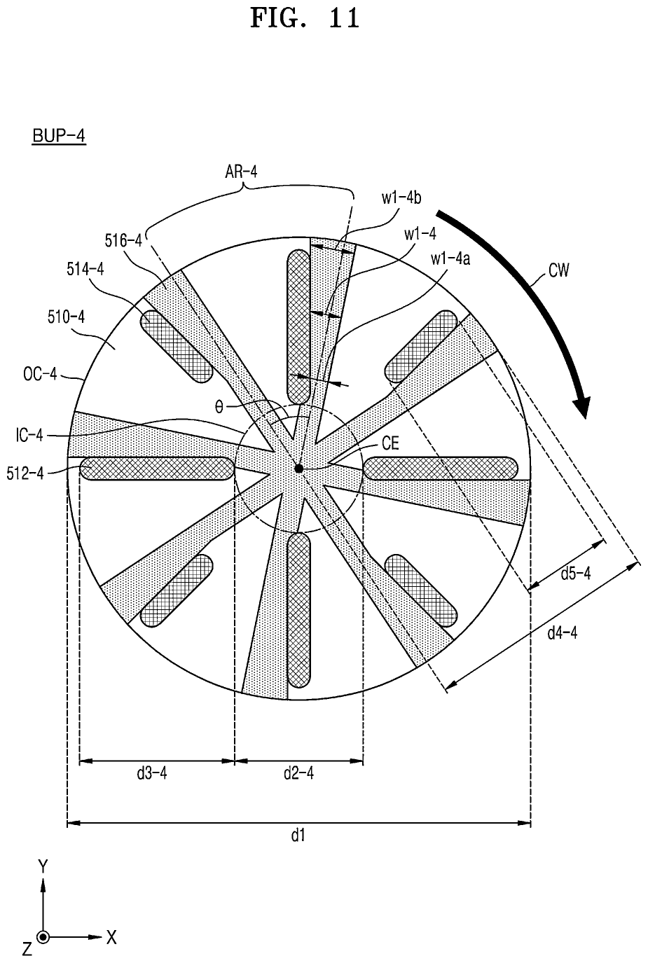

FIG. 11 is a plan view of a buffing pad included in a buffing treatment module according to an embodiment of the present inventive concept.

Specifically, a buffing pad BUP-4 may be substantially identical to the buffing pad BUP of FIGS. 4 and 5 except for the configuration of protrusion units 512-4 and 514-4 and trench units 516-4. In FIG. 11, the same descriptions as those given with reference to FIGS. 4 and 5 are briefly given or omitted.

The buffing pad BUP-4 may be included in the buffing treatment module 200 of FIGS. 1 and 2. The buffing treatment module (200 of FIGS. 1 and 2) may include the buffing pad BUP-4 that performs the buffing treatment on the substrate (120 of FIG. 2) by rotating while in contact with the substrate (120 in FIG. 2). The buffing pad BUP-4 may rotate according to the rotation of the buffing head (500 in FIGS. 2 and 3). In FIG. 11, the buffing pad BUP-4 rotates clockwise CW.

The buffing pad BUP-4 may include a circular base unit 510-4. The base unit 510-4 may have an outer circle OC-4 and an inner circle IC-4 that is located within the outer circle OC-4. The inner circle IC-4 may be a virtual inner circle that is located inside the base unit 510-4.

The outer circle OC-4 of the base unit 510-4 may have a diameter d1. In embodiments of the present inventive concept, the diameter d1 may be about 60 mm to about 100 mm. In embodiments of the present inventive concept, the diameter d1 may be about 67 mm. The diameter of the outer circle OC-4 of the base unit 510-4, that is, the diameter d1, may be less than the diameter of the substrate (120 of FIG. 2). The inner circle IC-4 may have a diameter d2-4. In embodiments of the present inventive concept, the diameter d2-4 may be about 10 mm to about 30 mm.

The buffing pad BUP-4 may include a plurality of protrusion units 512-4 and 514-4 that protrude from the surface of the base unit 510-4 within the circular base unit 510-4. The protrusion units 512-4 and 514-4 may be provided to facilitate polishing of the substrate (120 in FIG. 2) during the buffing treatment, especially the buffing polishing treatment.

The protrusion units 512-4 and 514-4 may be spaced apart from each other in a circumferential direction of the base unit 510-4. The protrusion units 512-4 and 514-4 may include long protrusion units 512-4, which have a long length, and short protrusion units 514-4, which have a short length, in a radial direction of the base unit 510-4. The long protrusion units 512-4 and the short protrusion units 514-4 may be alternately arranged in the circumferential direction of the base unit 510-4.

The long protrusion units 512-4 may contact the inner circle IC-4. For example, the long protrusion units 512-4 may extend to a boundary of the inner circle IC-4. The short protrusion units 514-4 might not contact the inner circle IC-4. The long protrusion units 512-4 may have a length d3-4 in the radial direction of the base unit 510-4. In embodiments of the present inventive concept, the length d3-4 may be about 20 mm to about 30 mm. The short protrusion units 514-4 may have a length d5-4 in the radial direction of the base unit 510-4. In embodiments of the present inventive concept, the length d5-4 may be about 10 mm to about 15 mm. The lengths d3-4 and d5-4 of the protrusion units 512-4 and 514-4 may be less than the length d4-4 of the trench units 516-4 in the radial direction of the base unit 510-4.

The buffing pad BUP-4 may include the plurality of trench units 516-4 that are positioned adjacent to the protrusion units 512-4 and 514-4 and extending from the center portion to the edge portion of the base unit 510-4. The trench units 516-4 may be provided to easily discharge treatment liquids such as deionized water, chemical liquid, and slurry supplied to the substrate (120 in FIG. 2) during the buffing treatment, especially the buffing cleaning treatment. The trench units 516-4 may extend from the inside of the base unit 510-4, particularly from the center point CE thereof, to the outer circle OC-4.

The trench units 516-4 are spaced apart from each other in the circumferential direction of the base unit 510-4. The trench units 516-4 may have a width w1-4. In embodiments of the present inventive concept, w1-4 may be about 2 mm to about 4 mm. The width of the trench units 516-4 may gradually increase in the radial direction of the base unit 510-4. The width of the trench units 516-4 may gradually increase from the center portion of the base unit 510-4 to the outer circle OC-4.

For example, the trench units 516-4 may have a width w1-4a in an area that is adjacent to the inner circle IC-4 and may have a width w1-4b in the area of the outer circle OC-4. For example, the portions of the trench units 516-4 with the width w1-4a may be adjacent to inner circle IC-4, and the portions of the trench units 516-4 with the width w1-4a may be adjacent to the edge portion, in the outer circle OC-4, of the base unit 510-4. The width w1-4b may be greater than the width w1-4a. When the width w1-4b is greater than the width w1-4a, treatment liquids such as deionized water, chemical liquid, and slurry supplied to the substrate (120 in FIG. 2) during the buffing treatment, especially the buffing cleaning treatment, may be discharged more easily.

The trench units 516-4 may be in contact with the protrusion units 512-4 and 514-4 in the circumferential direction of the base unit 510-4. The trench units 516-4 extend from the central portion of the base unit 510-4 to the outer circle OC-4. The trench units 516-4 may be arranged at front ends of the protrusion units 512-4 and 514-4 according to the rotation direction of the buffing head (500 in FIGS. 2 and 3), that is, the rotation direction of the buffing pad BUP-4.

In FIG. 11, as the buffing pad BUP-4 rotates clockwise CW, the trench units 516-4 may be arranged on the right side of the protrusion units 512-4 and 514-4. The trench units 516-4 may be a plurality of long trench units with a long length in the radial direction of the base unit 510-4. The trench units 516-4 may have a length d4-4 in the radial direction of the base unit 510-4. In embodiments of the present inventive concept, the length d4-4 may be about 30 mm to about 50 mm.

The buffing pad BUP-4 may include the base unit 510-4 having the center point CE. The base unit 510-4 may include a circular sector AR-4 based on the center point CE. The base unit 510-4 herein may include eight circular sectors AR-4 each having a central angle θ of 45 degrees. One circular sector AR-4 may include one of the long protrusion unit 512-4 or the short protrusion unit 514-4, and at least one trench unit 516-4 based on area.

The buffing pad BUP-4 configured in this manner may include the protrusion units 512-4 and 514-4 and the trench units 516-4 within the base unit 510-4. Among the base unit 510-4, the protrusion units 512-4 and 514-4, and the trench units 516-4, the base unit 510-4 may have the largest area.

In addition, according to the arrangement of the protrusion units 512-4 and 514-4 and the trench units 516-4 in the base unit 510-4, the buffing pad BUP-4 may facilitate the buffing treatment and may easily discharge the treatment liquids such as deionized water, chemical liquid, and slurry during the buffing treatment. Accordingly, by using the buffing pad BUP-4 according to an embodiment of the present inventive concept, it is possible to suppress the occurrence of scratches on the substrate (120 in FIG. 2) during the buffing treatment and to easily remove small particles.

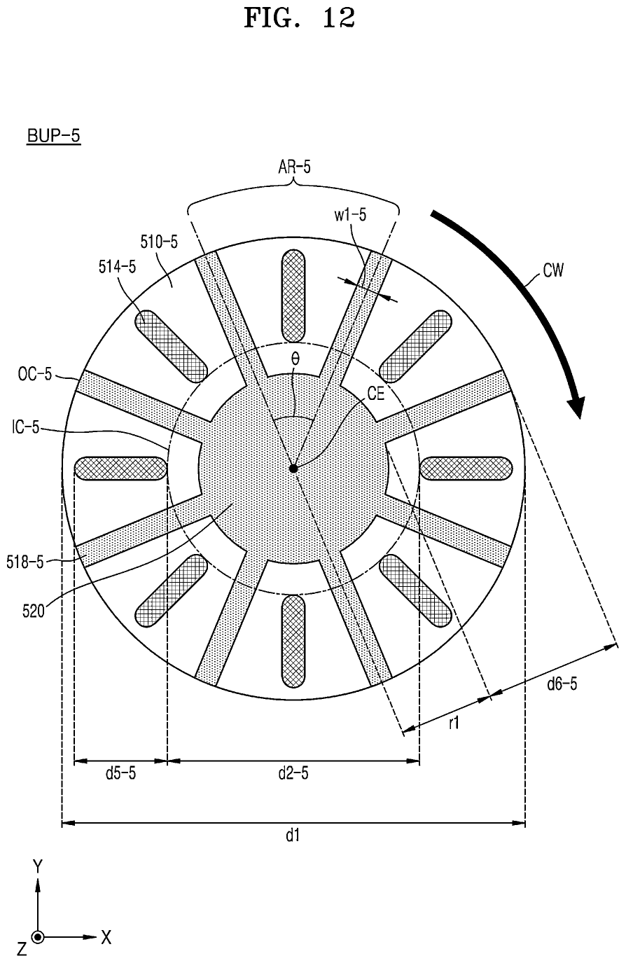

FIG. 12 is a plan view of a buffing pad included in a buffing treatment module according to an embodiment of the present inventive concept.

Specifically, a buffing pad BUP-5 is substantially identical to the buffing pad BUP in FIGS. 4 and 5 except for the configuration of protrusion units 514-5, trench units 518-5, and a central trench unit 520. In FIG. 12, the same descriptions as those given with reference to FIGS. 4 and 5 are briefly given or omitted.

The buffing pad BUP-5 may be included in the buffing treatment module 200 of FIGS. 1 and 2. The buffing treatment module (200 of FIGS. 1 and 2) may include the buffing pad BUP-5 that performs the buffing treatment on the substrate (120 of FIG. 2) by rotating while in contact with the substrate (120 in FIG. 2). The buffing pad BUP-5 may rotate according to the rotation of the buffing head (500 in FIGS. 2 and 3). In FIG. 12, the buffing pad BUP-5 rotates clockwise CW.

The buffing pad BUP-5 may include a circular base unit 510-5. The base unit 510-5 may have an outer circle OC-5 and an inner circle IC-5 that is located within the outer circle OC-5. The inner circle IC-5 may be a virtual inner circle located inside the base unit 510-5.

The outer circle OC-5 of the base unit 510-5 may have a diameter d1. In embodiments of the present inventive concept, the diameter d1 may be about 60 mm to about 100 mm. In embodiments of the present inventive concept, the diameter d1 may be about 67 mm. The diameter of the outer circle OC-5 of the base unit 510-5, that is, the diameter d1, may be less than the diameter of the substrate (120 of FIG. 2). The inner circle IC-5 may have a diameter d2-5. In embodiments of the present inventive concept, the diameter d2-5 may be about 20 mm to about 40 mm.

The buffing pad BUP-5 may include a plurality of protrusion units 514-5 that protrude from the surface of the base unit 510-5 within the circular base unit 510-5. The protrusion units 514-5 may be provided to facilitate polishing of the substrate (120 in FIG. 2) during the buffing treatment, especially the buffing polishing treatment.

The protrusion units 514-5 may be spaced apart from each other in a circumferential direction of the base unit 510-5. The protrusion units 514-5 may be short protrusion units with a short length in a radial direction of the base unit 510-5. The protrusion units 514-5 may contact the inner circle IC-5. For example, the protrusion units 514-5 may extend to the boundary of the inner circle IC-5. The protrusion units 514-5 may have a length d5-5 in the radial direction of the base unit 510-5. In embodiments of the present inventive concept, length d5-5 may be about 10 mm to about 15 mm. The length d5-5 of the protrusion units 514-5 may be less than the length d6-5 of the trench units 518-5 in the radial direction of the base unit 510-5.

The buffing pad BUP-5 may include the plurality of trench units 518-5 that is positioned adjacent to the protrusion units 514-5 and extending from the inner circle IC-5 to the outer circle OC-5. The trench units 518-5 may extend from the inner circle IC-5 to the edge portion of the base unit 510-5.

The buffing pad BUP-5 may include a central trench unit 520 that is installed in communication with all of the trench units 518-5 within the inner circle IC-5. The central trench unit 520 may have a length of r1 in the radial direction of the base unit 510-5. The central trench unit 520 may have a radius of r1 based on a center point CE of the base unit 510-5. In embodiments of the present inventive concept, the radius r1 may be about 20 mm to about 30 mm.

The trench units 518-5 and the central trench unit 520 may be provided to easily discharge treatment liquids such as deionized water, chemical liquid, and slurry supplied to the substrate (120 in FIG. 2) during the buffing treatment, especially the buffing cleaning treatment. The trench units 518-5 and the central trench unit 520 may extend from the inside of the base unit 510-5, particularly from the center point CE thereof, to the outer circle OC-5.

The trench units 518-5 are spaced apart from each other in the circumferential direction of the base unit 510-5. The trench units 518-5 may have a width w1-5. In embodiments of the present inventive concept, the width w1-5 may be about 2 mm to about 4 mm. The trench units 518-5 may be arranged to have a substantially uniform width in the radial direction of the base unit 510-5.

The trench units 518-5 may be spaced apart from the protrusion units 514-5. For example, the protrusion units 514-5 may be disposed between neighboring trench units 518-5. The trench units 518-5 may be arranged at front ends of the protrusion units 514-5 according to the rotation direction of the buffing head (500 in FIGS. 2 and 3), that is, the rotation direction of the buffing pad BUP-5. In FIG. 12, as the buffing pad BUP-5 rotates clockwise CW, the trench units 518-5 may be arranged on the right side of the protrusion units 514-5.

The trench units 518-5 may be long trench units with a long length in the radial direction of the base unit 510-5. The trench units 518-5 may be arranged adjacent to the protrusion units 514-5 in the circumferential direction of the base unit 510-5. The trench units 518-5 may have a length d6-5 in the radial direction of the base unit 510-5. In embodiments of the present inventive concept, the length d6-5 may be about 20 mm to about 30 mm.

The buffing pad BUP-5 may include the base unit 510-5 having the center point CE. The base unit 510-5 may include a circular sector AR-5 based on the center point CE. The base unit 510-5 herein may include eight circular sectors AR-5 each having a central angle θ of 45 degrees. One circular sector AR-5 may include one protrusion unit 514-5, one trench unit 518-5, and ⅛ of the central trench unit 520 based on area.

The buffing pad BUP-5 may include the protrusion units 514-5, the trench units 518-5, and the central trench unit 520 within the base unit 510-5. Among the base unit 510-5, the protrusion units 514-5, the trench units 518-5, and the central trench unit 520, the base unit 510-5 may have the largest area.

In addition, according to the arrangement of the protrusion units 514-5, the trench units 518-5, and the central trench unit 520 in the base unit 510-5, the buffing pad BUP-5 may facilitate the buffing treatment and may easily discharge the treatment liquids such as deionized water, chemical liquid, and slurry during the buffing treatment. Accordingly, using the buffing pad BUP-5 according to an embodiment of the present inventive concept, it is possible to suppress the occurrence of scratches on the substrate (120 in FIG. 2) during the buffing treatment and to easily remove small particles.

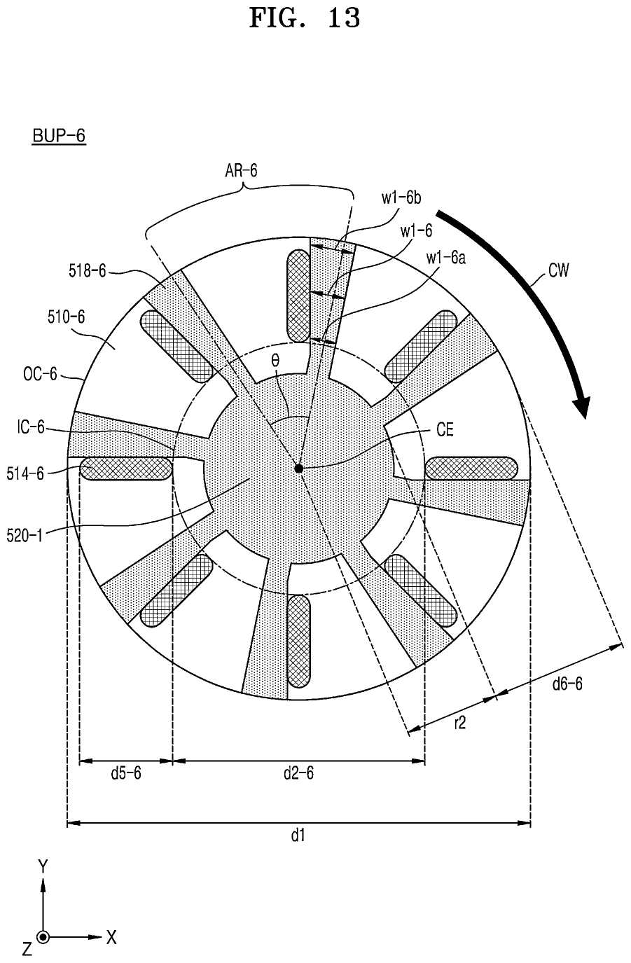

FIG. 13 is a plan view of a buffing pad included in a buffing treatment module according to an embodiment of the present inventive concept.

Specifically, a buffing pad BUP-6 may be substantially the same as the buffing pad BUP of FIGS. 4 and 5, except for the configuration of protrusion units 514-6, trench units 518-6, and a central trench unit 520-1. In FIG. 13, the same descriptions as those given with reference to FIGS. 4 and 5 are briefly given or omitted.

The buffing pad BUP-6 may be included in the buffing treatment module 200 of FIGS. 1 and 2. The buffing treatment module (200 of FIGS. 1 and 2) may include the buffing pad BUP-6 that performs the buffing treatment on the substrate (120 of FIG. 2) by rotating while in contact with the substrate (120 in FIG. 2). The buffing pad BUP-6 may rotate according to the rotation of the buffing head (500 in FIGS. 2 and 3). In FIG. 13, the buffing pad BUP-6 rotates clockwise CW.

The buffing pad BUP-6 may include a circular base unit 510-6. The base unit 510-6 may have an outer circle OC-6 and an inner circle IC-6 that is located within the outer circle OC-6. The inner circle IC-6 may be a virtual inner circle located inside the base unit 510-6.

The outer circle OC-6 of the base unit 510-6 may have a diameter d1. In embodiments of the present inventive concept, the diameter d1 may be about 60 mm to about 100 mm. In embodiments of the present inventive concept, the diameter d1 may be about 67 mm. The diameter of the outer circle OC-6 of the base unit 510-6, that is, the diameter d1, may be less than the diameter of the substrate (120 of FIG. 2). The inner circle IC-6 may have a diameter d2-6. In embodiments of the present inventive concept, the diameter d2-6 may be about 30 mm to about 50 mm.

The buffing pad BUP-6 may include a plurality of protrusion units 514-6 that protrude from the surface of the base unit 510-6 within the circular base unit 510-6. The protrusion units 514-6 may be provided to facilitate polishing of the substrate (120 in FIG. 2) during the buffing treatment, especially the buffing polishing treatment.

The protrusion units 514-6 may be spaced apart from each other in a circumferential direction on the base unit 510-6. The protrusion units 514-6 may be short protrusion units with a short length in a radial direction of the base unit 510-6. The protrusion units 514-6 may contact the inner circle IC-6. For example, the protrusion units 514-6 may extend to a boundary of the inner circle IC-6. The protrusion units 514-6 may have a length d5-6 in the radial direction of the base unit 510-6. In embodiments of the present inventive concept, the length d5-6 may be about 10 mm to about 15 mm. The length d5-6 of the protrusion units 514-6 may be less than the length d6-6 of the trench units 518-6 in the radial direction of the base unit 510-6.

The buffing pad BUP-6 may include the plurality of trench units 518-6 that are positioned adjacent to the protrusion units 514-6 and extending from the inner circle IC-6 to the outer circle OC-6. The trench units 518-6 may extend from the inner circle IC-6 to the edge portion of the base unit 510-6.

The buffing pad BUP-6 may include a central trench unit 520-1 that is installed in communication with all of the trench units 518-6 inside the inner circle IC-6. The central trench unit 520-1 may be arranged in a partial area that is inside the inner circle IC-6.

The central trench unit 520-1 may have a length of r2 in the radial direction of the base unit 510-6. The central trench unit 520-1 may have a radius of r2 based on a center point CE of the base unit 510-6. In embodiments of the present inventive concept, the radius r2 may be about 20 mm to about 30 mm.

The trench units 518-6 and the central trench unit 520-1 may be provided to easily discharge treatment liquids such as deionized water, chemical liquid, and slurry supplied to the substrate (120 in FIG. 2) during the buffing treatment, especially the buffing cleaning treatment. The trench units 518-6 and the central trench unit 520-1 may extend from the inside of the base unit 510-6, particularly from the center point CE thereof, to the outer circle OC-6.

The trench units 518-6 may be spaced apart from each other in the circumferential direction of the base unit 510-6. The trench units 518-6 may have a width w1-6. In embodiments of the present inventive concept, the width w1-6 may be about 2 mm to about 4 mm. The width of the trench units 518-6 may gradually increase in the radial direction of the base unit 510-6. The width of the trench units 518-6 may gradually increase from the center portion of the base unit 510-6 to the outer circle OC-6.

For example, the trench units 518-6 may have a width w1-6a in an area that is adjacent to the inner circle IC-6 and may have a width w1-6b in the area of the outer circle OC-6. For example, the portions of the trench units 518-6 with the width w1-6a may be adjacent to inner circle IC-6, and the portions of the trench units 518-6 with the width w1-6b may be adjacent to the edge portion, in the outer circle OC-6, of the base unit 510-6. The width w1-6b may be greater than the width w1-6a. When the width w1-6b is greater than the width w1-6a, treatment liquids such as deionized water, chemical liquid, and slurry supplied to the substrate (120 in FIG. 2) during the buffing treatment, especially the buffing cleaning treatment, may be discharged more easily.

The trench units 518-6 may be in contact with the protrusion units 514-6 in the circumferential direction of the base unit 510-6. The trench units 518-6 may be arranged at front ends of the protrusion units 514-6 according to the rotation direction of the buffing head (500 in FIGS. 2 and 3), that is, the rotation direction of the buffing pad BUP-6. In FIG. 13, as the buffing pad BUP-6 rotates clockwise CW, the trench units 518-6 may be arranged on the right side of the protrusion units 514-6.

The trench units 518-6 may be long trench units with a long length in the radial direction of the base unit 510-6. The trench units 518-6 may be arranged in contact with the protrusion units 514-6 in the circumferential direction of the base unit 510-6. The trench units 518-6 may have a length d6-6 in the radial direction of the base unit 510-6. In embodiments of the present inventive concept, the length d6-6 may be about 20 mm to about 30 mm.

The buffing pad BUP-6 may include the base unit 510-6 having the center point CE. The base unit 510-6 may include a circular sector AR-6 based on the center point CE. The base unit 510-6 herein may include eight circular sectors AR-6 each having a central angle θ of 45 degrees. One circular sector AR-6 may include one protrusion unit 514-6, one trench unit 518-6, and ⅛^{th} of the central trench unit 520-1 based on area.

The buffing pad BUP-6 configured in this manner may include the protrusion units 514-6, the trench units 518-6, and the central trench unit 520-1 within the base unit 510-6. Among the base unit 510-6, the protrusion units 514-6, the trench units 518-6, and the central trench unit 520-1, the base unit 510-6 may have the largest area.

In addition, according to the arrangement of the protrusion units 514-6, the trench units 518-6, and the central trench unit 520-1 in the base unit 510-6, the buffing pad BUP-6 may facilitate the buffing treatment and may easily discharge the treatment liquids such as deionized water, chemical liquid, and slurry during the buffing treatment. Accordingly, by using the buffing pad BUP-6 according to an embodiment of the present inventive concept, it is possible to suppress the occurrence of scratches on the substrate (120 in FIG. 2) during the buffing treatment and to easily remove small particles.

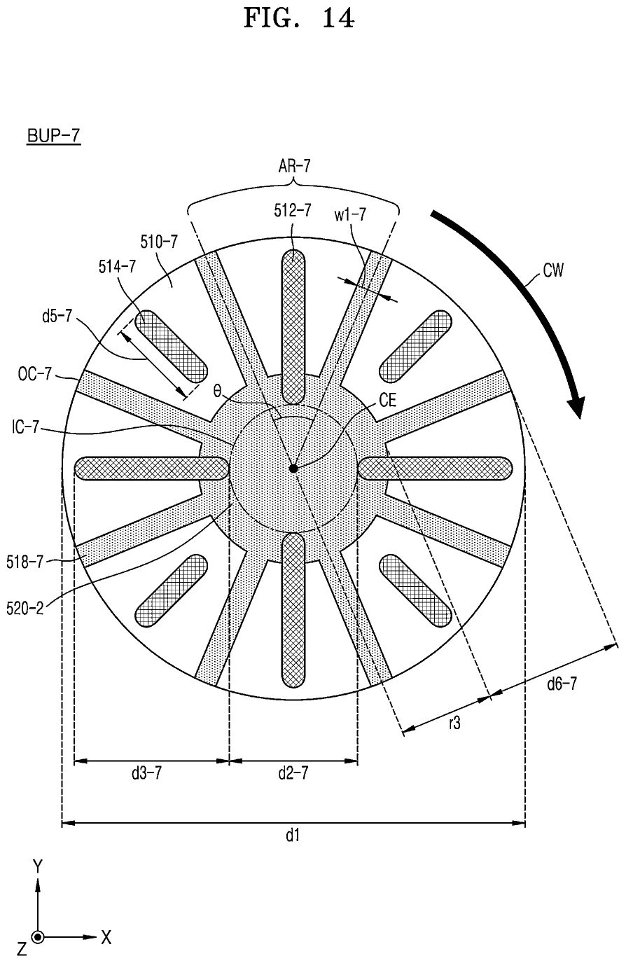

FIG. 14 is a plan view of a buffing pad included in a buffing treatment module according to an embodiment of the present inventive concept.

Specifically, a buffing pad BUP-7 is substantially identical to the buffing pad BUP in FIGS. 4 and 5 except for the configuration of protrusion units 512-7 and 514-7, trench units 518-7, and a central trench unit 520-2. In FIG. 14, the same descriptions as those given with reference to FIGS. 4 and 5 are briefly given or omitted.

The buffing pad BUP-7 may be included in the buffing treatment module 200 of FIGS. 1 and 2. The buffing treatment module (200 of FIGS. 1 and 2) may include the buffing pad BUP-7 that performs the buffing treatment on the substrate (120 of FIG. 2) by rotating while in contact with the substrate (120 in FIG. 2). The buffing pad BUP-7 may rotate according to the rotation of the buffing head (500 in FIGS. 2 and 3). In FIG. 14, the buffing pad BUP-7 rotates clockwise CW.

The buffing pad BUP-7 may include a circular base unit 510-7. The base unit 510-7 may have an outer circle OC-7 and an inner circle IC-7 that is located within the outer circle OC-7. The inner circle IC-7 may be a virtual inner circle located inside the base unit 510-7. The outer circle OC-7 of the base unit 510-7 may have a diameter d1. In embodiments of the present inventive concept, the diameter d1 may be about 60 mm to about 100 mm. In embodiments of the present inventive concept, the diameter d1 may be about 67 mm. The diameter of the outer circle OC-7 of the base unit 510-7, that is, the diameter d1, may be less than the diameter of the substrate (120 of FIG. 2). The inner circle IC-7 may have a diameter d2-7. In embodiments of the present inventive concept, the diameter d2-7 may be about 10 mm to about 20 mm.

The buffing pad BUP-7 may include a plurality of protrusion units 512-7 and 514-7 that protrude from the surface of the base unit 510-7 within the circular base unit 510-7. The protrusion units 512-7 and 514-7 may be provided to facilitate polishing of the substrate (120 in FIG. 2) during the buffing treatment, especially the buffing polishing treatment.

The protrusion units 512-7 and 514-7 may be spaced apart from each other in the circumferential direction of the base unit 510-7. The protrusion unit 512-7 and 514-7 may include a plurality of long protrusion units 512-7, which have a long length in a radial direction of the base unit 510-7, and a plurality of short protrusion units 514-7, which have a short length in the radial direction of the base unit 510-7. The long protrusion units 512-7 and the short protrusion units 514-7 may be alternately arranged in the circumferential direction of the base unit 510-7.

The long protrusion units 512-7 may contact the inner circle IC-7. For example, the long protrusion units 512-7 may extend to a boundary of the inner circle IC-7. The long protrusion units 512-7 may have a length d3-7 in the radial direction of the base unit 510-7. In embodiments of the present inventive concept, the length d3-7 may be about 20 mm to about 30 mm. The short protrusion units 514-7 might not contact the inner circle IC-7.

The short protrusion units 514-7 may have a length d5-7 in the radial direction of the base unit 510-7. In embodiments of the present inventive concept, the length d5-7 may be about 10 mm to about 15 mm. The length d5-7 of the short protrusion units 514-7 may be less than the length d6-7 of the trench units 518-7 in the radial direction of the base unit 510-7.

The buffing pad BUP-7 may include the plurality of trench units 518-7 that are positioned adjacent to the protrusion units 512-7 and 514-7 and extending from the inner circle IC-7 to the outer circle OC-7. The trench units 518-7 may extend from the inner circle IC-7 to the edge portion of the base unit 510-7.

The buffing pad BUP-7 may include a central trench unit 520-2 that is installed in communication with all of the trench units 518-7 inside and around the inner circle IC-7. The central trench unit 520-2 may have a length of r3 in the radial direction of the base unit 510-7. The central trench unit 520-2 may have a radius of r3 based on a center point CE of the base unit 510-7. In embodiments of the present inventive concept, the radius r3 may be about 20 mm to about 30 mm.

The trench units 518-7 and the central trench unit 520-2 may be provided to easily discharge treatment liquids such as deionized water, chemical liquid, and slurry supplied to the substrate (120 in FIG. 2) during the buffing treatment, especially the buffing cleaning treatment. The trench units 518-7 and the central trench unit 520-2 may extend from the inside of the base unit 510-7, particularly from the center point CE thereof, to the outer circle OC-7.

The trench units 518-7 may be spaced apart from each other in the circumferential direction of the base unit 510-7. The trench units 518-7 may have a width w1-7. In embodiments of the present inventive concept, the width w1-7 may be about 2 mm to about 4 mm. The trench units 518-7 may be arranged to have a substantially uniform width in the radial direction of the base unit 510-7.

The trench units 518-7 may be spaced apart from the protrusion units 512-7 and 514-7. The trench units 518-7 may be arranged at front ends of the protrusion units 512-7 and 514-7 according to the rotation direction of the buffing head (500 in FIGS. 2 and 3), that is, the rotation direction of the buffing pad BUP-7. In FIG. 14, as the buffing pad BUP-7 rotates clockwise CW, the trench units 518-7 may be arranged on the right side of the protrusion units 512-7 and 514-7.

The trench units 518-7 may be long trench units with a long length in the radial direction of the base unit 510-7. The trench units 518-7 may be arranged adjacent to the protrusion units 512-7 and 514-7 in the circumferential direction of the base unit 510-7. The trench units 518-7 may have a length d6-7 in the radial direction of the base unit 510-7. In embodiments of the present inventive concept, the length d6-7 may be about 20 mm to about 30 mm.

The buffing pad BUP-7 may include the base unit 510-7 having the center point CE. The base unit 510-7 may include a circular sector AR-7 based on the center point CE. The base unit 510-7 herein may include eight circular sectors AR-7 each having a central angle θ of 45 degrees. One circular sector AR-7 may include one of the long protrusion unit 512-7 and the short protrusion unit 514-7, at least one trench unit 518-7, and ⅛^{th} of the central trench unit 520-2 based on area.

The buffing pad BUP-7 may include the protrusion units 512-7 and 514-7, the trench units 518-7, and the central trench unit 520-2 within the base unit 510-7. Among the base unit 510-7, the protrusion units 512-7 and 514-7, the trench units 518-7, and the central trench unit 520-2, the base unit 510-7 may have the largest area.

In addition, according to the arrangement of the protrusion units 512-7 and 514-7, the trench units 518-7, and the central trench unit 520-2 in the base unit 510-7, the buffing pad BUP-7 may facilitate the buffing treatment and may easily discharge the treatment liquids such as deionized water, chemical liquid, and slurry during the buffing treatment. Accordingly, by using the buffing pad BUP-7 according to an embodiment of the present inventive concept, it is possible to suppress the occurrence of scratches on the substrate (120 in FIG. 2) during the buffing treatment and to easily remove small particles.

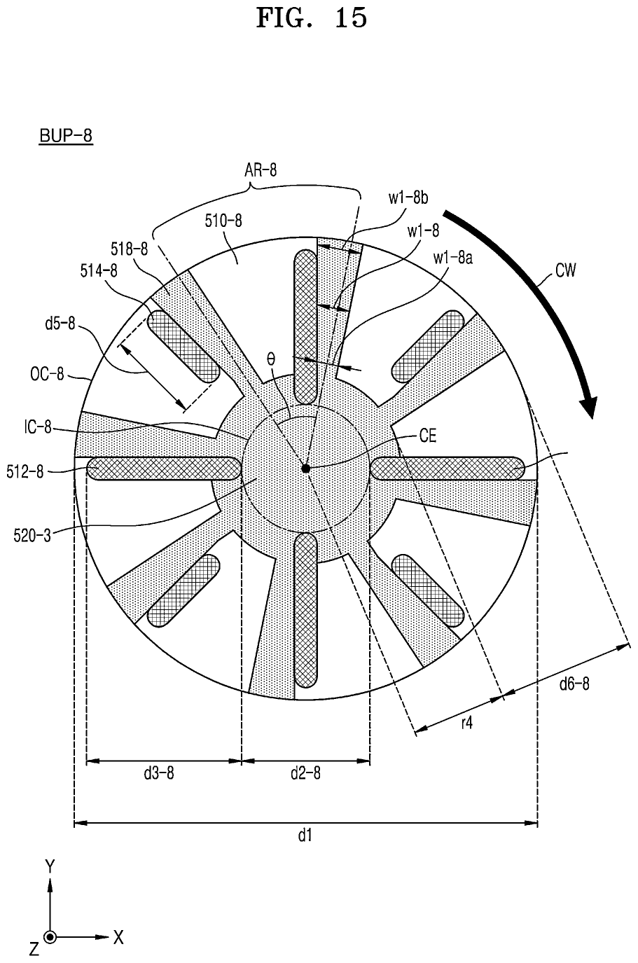

FIG. 15 is a plan view of a buffing pad included in a buffing treatment module according to an embodiment of the present inventive concept.

Specifically, a buffing pad BUP-8 is substantially identical to the buffing pad BUP in FIGS. 4 and 5 except for the configuration of protrusion units 512-8 and 514-8, trench units 518-8, and a central trench unit 520-3. In FIG. 15, the same descriptions as those given with reference to FIGS. 4 and 5 are briefly given or omitted.

The buffing pad BUP-8 may be included in the buffing treatment module 200 of FIGS. 1 and 2. The buffing treatment module (200 of FIGS. 1 and 2) may include the buffing pad BUP-8 that performs the buffing treatment on the substrate (120 of FIG. 2) by rotating while in contact with the substrate (120 in FIG. 2). The buffing pad BUP-8 may rotate according to the rotation of the buffing head (500 in FIGS. 2 and 3). In FIG. 15, the buffing pad BUP-8 rotates clockwise CW.

The buffing pad BUP-8 may include a circular base unit 510-8. The base unit 510-8 may have an outer circle OC-8 and an inner circle IC-8 that is located within the outer circle OC-8. The inner circle IC-8 may be a virtual inner circle located inside the base unit 510-8. The outer circle OC-8 of the base unit 510-8 may have a diameter d1. In embodiments of the present inventive concept, the diameter d1 may be about 60 mm to about 100 mm. In embodiments of the present inventive concept, the diameter d1 may be about 67 mm. The diameter of the outer circle OC-8 of the base unit 510-8, that is, the diameter d1, may be less than the diameter of the substrate (120 of FIG. 2). The inner circle IC-8 may have a diameter d2-8. In embodiments of the present inventive concept, the diameter d2-8 may be about 10 mm to about 20 mm.

The buffing pad BUP-8 may include a plurality of protrusion units 512-8 and 514-8 that protrude from the surface of the base unit 510-8 within the circular base unit 510-8. The protrusion units 512-8 and 514-8 may be provided to facilitate polishing of the substrate (120 in FIG. 2) during the buffing treatment, especially the buffing polishing treatment.

The protrusion units 512-8 and 514-8 may be spaced apart from each other in a circumferential direction of the base unit 510-8. The protrusion units 512-8 and 514-8 may include a plurality of long protrusion units 512-8, which have a long length in a radial direction of the base unit 510-8, and a plurality of short protrusion units 514-8, which have a short length in the radial direction of the base unit 510-8. The long protrusion units 512-8 and the short protrusion units 514-8 may be alternately arranged in the circumferential direction of the base unit 510-8.

The long protrusion units 512-8 may contact the inner circle IC-8. The long protrusion units 512-8 may have a length d3-8 in the radial direction of the base unit 510-8. In embodiments of the present inventive concept, the length d3-8 may be about 20 mm to about 30 mm. The short protrusion units 514-8 might not contact the inner circle IC-8.

The short protrusion units 514-8 may have a length d5-8 in the radial direction of the base unit 510-8. In embodiments of the present inventive concept, the length d5-8 may be about 10 mm to about 15 mm. The length d5-8 of the short protrusion units 514-8 may be less than the length d6-8 of the trench units 518-8 in the radial direction of the base unit 510-8.

The buffing pad BUP-8 may include the plurality of trench units 518-8 that are positioned adjacent to the protrusion units 512-8 and 514-8 and extending from the inner circle IC-8 to the outer circle OC-8. The trench units 518-8 may extend from the inner circle IC-8 to the edge portion of the base unit 510-8.

The buffing pad BUP-8 may include a central trench unit 520-3 that is installed in communication with all of the trench units 518-8 inside and around the inner circle IC-8. The central trench unit 520-3 may have a length of r4 in the radial direction of the base unit 510-8. The central trench unit 520-3 may have a radius of r4 based on a center point CE of the base unit 510-8. In embodiments of the present inventive concept, the radius r4 may be about 20 mm to about 30 mm.

The trench units 518-8 and the central trench unit 520-3 may be provided to easily discharge treatment liquids such as deionized water, chemical liquid, and slurry supplied to the substrate (120 in FIG. 2) during the buffing treatment, especially the buffing cleaning treatment. The trench units 518-8 and the central trench unit 520-3 may extend from the inside of the base unit 510-8, particularly from the center point CE thereof, to the outer circle OC-8.

The trench units 518-8 may be spaced apart from each other in the circumferential direction of the base unit 510-8. The trench units 518-8 may have a width w1-8. In embodiments of the present inventive concept, the width w1-8 may be about 2 mm to about 4 mm. The width of the trench units 518-8 may gradually increase in the radial direction of the base unit 510-8. The width of the trench units 518-8 may gradually increase from the center portion of the base unit 510-8 to the outer circle OC-8.

For example, the trench units 518-8 may have a width w1-8a in an area that is adjacent to the inner circle IC-8 and may have a width w1-8b in area of the outer circle OC-8. For example, the portions of the trench units 518-8 with the width w1-8a may be adjacent to inner circle IC-8, and the portions of the trench units 518-8 with the width w1-8b may be adjacent to the edge portion, in the outer circle OC-8, of the base unit 510-8. The width w1-8b may be greater than the width w1-8a. When the width w1-8b is greater than the width w1-8a, treatment liquids such as deionized water, chemical liquid, and slurry supplied to the substrate (120 in FIG. 2) during the buffing treatment, especially the buffing cleaning treatment, may be discharged more easily.

The trench units 518-8 may be in contact with the protrusion units 512-8 and 514-8 in the circumferential direction of the base unit 510-8. The trench units 518-8 may be arranged at front ends of the protrusion units 512-8 and 514-8 according to the rotation direction of the buffing head (500 in FIGS. 2 and 3), that is, the rotation direction of the buffing pad BUP-8. In FIG. 15, as the buffing pad BUP-8 rotates clockwise CW, the trench units 518-8 may be arranged on the right side of the protrusion units 512-8 and 514-8.

The trench units 518-8 may be long trench units with a long length in the radial direction of the base unit 510-8. The trench units 518-8 may be arranged in contact with the protrusion units 512-8 and 514-8 in the circumferential direction of the base unit 510-8. The trench units 518-8 may have a length d6-8 in the radial direction of the base unit 510-8. In embodiments of the present inventive concept, the length d6-8 may be about 20 mm to about 30 mm.

The buffing pad BUP-8 may include the base unit 510-8 having the center point CE. The base unit 510-8 may include a circular sector AR-8 based on the center point CE. The base unit 510-8 herein may include eight circular sectors AR-8 each having a central angle θ of 45 degrees. One circular sector AR-8 may include one of the long protrusion unit 512-8 and the short protrusion unit 514-8, at least one trench unit 518-8, and ⅛^{th} of the central trench unit 520-3 based on area.

The buffing pad BUP-8 may include the protrusion units 512-8 and 514-8, the trench units 518-8, and the central trench unit 520-3 within the base unit 510-8. Among the base unit 510-8, the protrusion units 512-8 and 514-8, the trench units 518-8, and the central trench unit 520-3, the base unit 510-8 may have the largest area.

In addition, according to the arrangement of the protrusion units 512-8 and 514-8, the trench units 518-8, and the central trench unit 520-3 in the base unit 510-8, the buffing pad BUP-8 may facilitate the buffing treatment and may easily discharge the treatment liquids such as deionized water, chemical liquid, and slurry during the buffing treatment. Accordingly, by using the buffing pad BUP-8 according to an embodiment of the present inventive concept, it is possible to suppress the occurrence of scratches on the substrate (120 in FIG. 2) during the buffing treatment and to easily remove small particles.

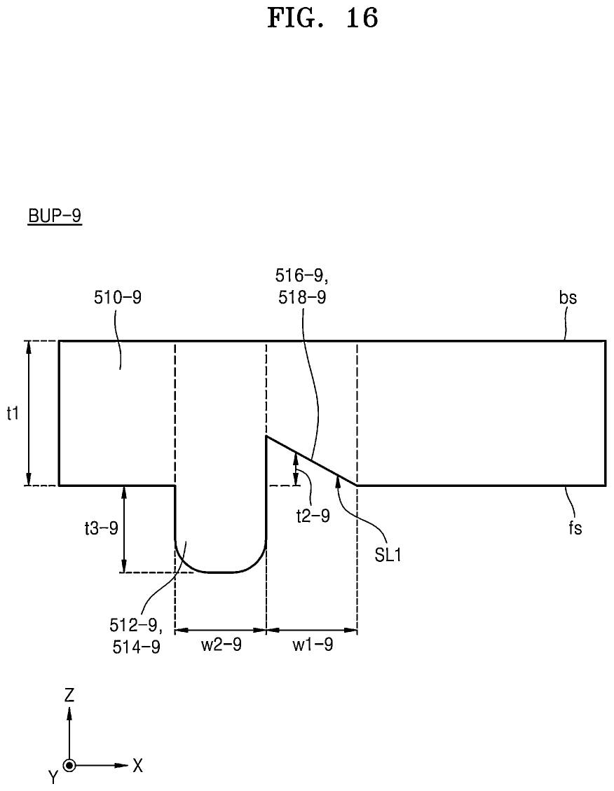

FIG. 16 is a cross-sectional view of a buffing pad included in a buffing treatment module according to an embodiment of the present inventive concept.

Specifically, a buffing pad BUP-9 may include protrusion units 512-9 and 514-9 and trench units 516-9 and 518-9 arranged within a base unit 510-9. The buffing pad BUP-9 may be applied to the buffing pads BUP, BUP-1 to BUP-8 described above. In FIG. 16, the contents previously described regarding the buffing pads BUP, BUP-1 to BUP-8 are briefly given or omitted.

The buffing pad BUP-9 may include the base unit 510-9. The base unit 510-9 may include a back surface bs and a front surface fs. The base unit 510-9 may have a thickness t1. In embodiments of the present inventive concept, the thickness t1 may be about 5 mm to about 10 mm.

The buffing pad BUP-9 may include the protrusion units 512-9 and 514-9 that protrude from the front surface fs of the base unit 510-9. The protrusion units 512-9 and 514-9 may include long protrusion units 512-9 and short protrusion units 514-9, as described above.

The protrusion units 512-9 and 514-9 may have a thickness t3-9 from the front surface fs of the base unit 510-9. In embodiments of the present inventive concept, t3-9 may be about 1 mm to about 5 mm. The protrusion units 512-9 and 514-9 may have a width w2-9. In embodiments of the present inventive concept, the width w2-9 may be about 2 mm to about 4 mm. The protrusion units 512-9 and 514-9 may be provided to facilitate polishing of the substrate (120 in FIG. 2) during the buffing treatment, especially the buffing polishing treatment.

The buffing pad BUP-9 may include the trench units 516-9 and 518-9 in contact with the protrusion units 512-9 and 514-9. The trench units 516-9 and 518-9 may include long trench units 516-9 and short trench units 518-9, similarly to what was previously described. The protrusion units 512-9 and 514-9 are shown as being in contact with the trench units 516-9 and 518-9 herein, but the protrusion units 512-9 and 514-9 may be spaced apart from the trench units 516-9 and 518-9.

The trench units 516-9 and 518-9 may be arranged at a depth t2-9 from the front surface fs of the base unit 510-9. In embodiments of the present inventive concept, the depth t2-9 may be about 1 mm to about 5 mm. The trench units 516-9 and 518-9 may have a width w1-9. In embodiments of the present inventive concept, the width w1-9 may be about 2 mm to about 4 mm. The trench units 516-9 and 518-9 may include an inclined surface SL1 that is inclined from the surface of the base unit 510-9 to the inside of the base unit 510-9. For example, the inclined surface SL1 may be inclined from the front surface fs of the base unit 510-9.

The trench units 516-9 and 518-9 may be provided to easily discharge treatment liquids such as deionized water, chemical liquid, and slurry supplied to the substrate (120 in FIG. 2) during the buffing treatment, especially the buffing cleaning treatment.

In addition, since the trench units 516-9 and 518-9 include the inclined surface SL1, the treatment liquids may be discharged more easily. Accordingly, using the buffing pad BUP-9 of the inventive concept, it is possible to suppress the occurrence of scratches on the substrate (120 in FIG. 2) during the buffing treatment and to easily remove small particles.

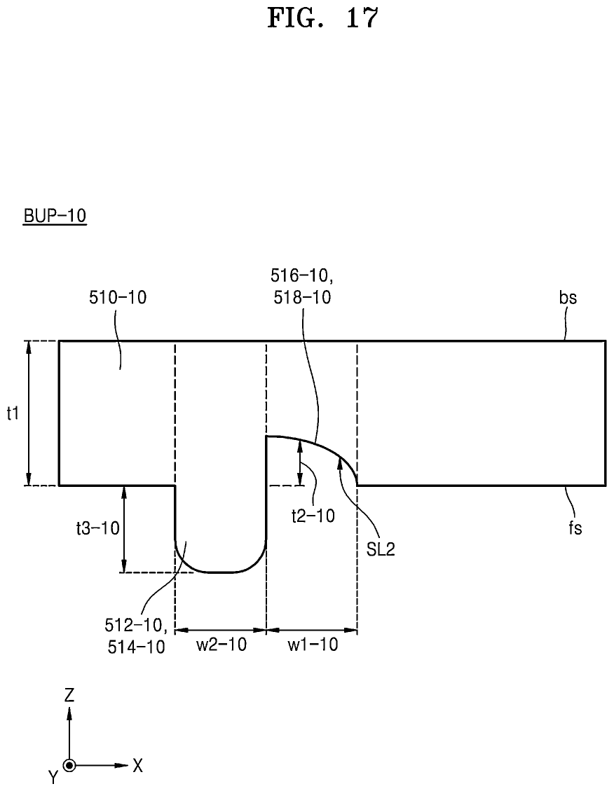

FIG. 17 is a cross-sectional view of a buffing pad included in a buffing treatment module according to an embodiment of the present inventive concept.

Specifically, a buffing pad BUP-10 may include protrusion units 512-10 and 514-10 and trench units 516-10 and 518-10 arranged within a base unit 510-10. The buffing pad BUP-10 may be applied to the buffing pads BUP, BUP-1 to BUP-8 described above. In FIG. 17, the contents previously described regarding the buffing pads BUP, BUP-1 to BUP-8 are briefly given or omitted.

The buffing pad BUP-10 may include the base unit 510-10. The base unit 510-10 may include a back surface bs and a front surface fs. The base unit 510-10 may have a thickness t1. In embodiments of the present inventive concept, the thickness t1 may be about 5 mm to about 10 mm.

The buffing pad BUP-10 may include the protrusion units 512-10 and 514-10 that protrude from the front surface fs of the base unit 510-10. The protrusion units 512-10 and 514-10 may include long protrusion units 512-10 and short protrusion units 514-10, as described above.

The protrusion units 512-10 and 514-10 may have a thickness t3-10 from the front surface fs of the base unit 510-10. In embodiments of the present inventive concept, the thickness t3-10 may be about 1 mm to about 5 mm. The protrusion units 512-10 and 514-10 may have a width w2-10. In embodiments of the present inventive concept, the width w2-10 may be about 2 mm to about 4 mm. The protrusion units 512-10 and 514-10 may be provided to facilitate polishing of the substrate (120 in FIG. 2) during the buffing treatment, especially the buffing polishing treatment.

The buffing pad BUP-10 may include the trench units 516-10 and 518-10 in contact with the protrusion units 512-10 and 514-10. The trench units 516-10 and 518-10 may include long trench units 516-10 and short trench units 518-10, similarly to what was previously described. The protrusion units 512-10 and 514-10 are shown as being in contact with the trench units 516-10 and 518-10 herein, but the protrusion units 512-10 and 514-10 may be spaced apart from the trench units 516-10 and 518-10.

The trench units 516-10 and 518-10 may be arranged at a depth t2-10 from the front surface fs of the base unit 510-10. In embodiments of the present inventive concept, the depth t2-10 may be about 1 mm to about 5 mm. The trench units 516-10 and 518-10 may have a width w1-10. In embodiments of the present inventive concept, the width w1-10 may be about 2 mm to about 4 mm.

The trench units 516-10 and 518-10 may include a curved surface SL2 that is curved from the front surface fs of the base unit 510-10 to the inside of the base unit 510-10. The curved surface SL2 may be a convex surface that makes the trench units 516-10 and 518-10 convex.

The trench units 516-10 and 518-10 may be provided to easily discharge treatment liquids such as deionized water, chemical liquid, and slurry supplied to the substrate (120 in FIG. 2) during the buffing treatment, especially the buffing cleaning treatment.

In addition, since the trench units 516-10 and 518-10 include the curved surface SL2, the treatment liquids may be discharged more easily. Accordingly, by using the buffing pad BUP-10 according to an embodiment of the present inventive concept, it is possible to suppress the occurrence of scratches on the substrate (120 in FIG. 2) during the buffing treatment and to easily remove small particles.

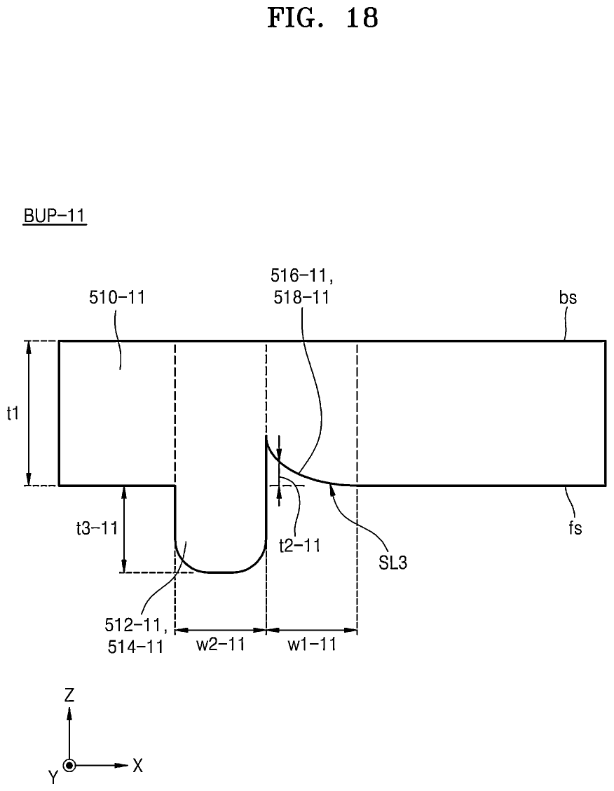

FIG. 18 is a cross-sectional view of a buffing pad included in a buffing treatment module according to an embodiment of the present inventive concept.

Specifically, a buffing pad BUP-11 may include protrusion units 512-11 and 514-11 and trench units 516-11 and 518-11 arranged within a base unit 510-11. The buffing pad BUP-11 may be applied to the buffing pads BUP, BUP-1 to BUP-8 described above. In FIG. 18, the contents previously described regarding the buffing pads BUP, BUP-1 to BUP-8 are briefly given or omitted.

The buffing pad BUP-11 may include the base unit 510-11. The base unit 510-11 may include a back surface bs and a front surface fs. The base unit 510-11 may have a thickness t1. In embodiments of the present inventive concept, the thickness t1 may be about 5 mm to about 10 mm.

The buffing pad BUP-11 may include protrusion units 512-11 and 514-11 that protrude from the front surface fs of the base unit 510-11. The protrusion units 512-11 and 514-11 may include long protrusion units 512-11 and short protrusion units 514-11, as described above.

The protrusion units 512-11 and 514-11 may have a thickness t3-11 from the front surface fs of the base unit 510-11. In embodiments of the present inventive concept, the thickness t3-11 may be about 1 mm to about 5 mm. The protrusion units 512-11 and 514-11 may have a width w2-11. In embodiments of the present inventive concept, the width w2-11 may be about 2 mm to about 4 mm. The protrusion units 512-11 and 514-11 may be provided to facilitate polishing of the substrate (120 in FIG. 2) during the buffing treatment, especially the buffing polishing treatment.

The buffing pad BUP-11 may include the trench units 516-11 and 518-11 in contact with the protrusion units 512-11 and 514-11. The trench units 516-11 and 518-11 may include long trench units 516-11 and short trench units 518-11, similarly to what was previously described. The protrusion units 512-11 and 514-11 are shown as being in contact with the trench units 516-11 and 518-11 herein, but the protrusion units 512-11 and 514-11 may be spaced apart from the trench units 516-11 and 518-11.

The trench units 516-11 and 518-11 may be arranged at a depth t2-11 from the front surface fs of the base unit 510-11. In embodiments of the present inventive concept, t2-11 may be about 1 mm to about 5 mm. The trench units 516-11 and 518-11 may have a width w1-11. In embodiments of the present inventive concept, the width w1-11 may be about 2 mm to about 4 mm.

The trench units 516-11 and 518-11 may include a curved surface SL3 that is curved from the front surface fs of the base unit 510-11 to the inside of the base unit 510-11. The curved surface SL3 may be a concave surface that makes the trench units 516-11 and 518-11 concave.

The trench units 516-11 and 518-11 may be provided to easily discharge treatment liquids such as deionized water, chemical liquid, and slurry supplied to the substrate (120 in FIG. 2) during the buffing treatment, especially the buffing cleaning treatment.

In addition, since the trench units 516-11 and 518-11 include the curved surface SL3, the treatment liquids may be discharged more easily. Accordingly, by using the buffing pad BUP-11 according to an embodiment of the present inventive concept, it is possible to suppress the occurrence of scratches on the substrate (120 in FIG. 2) during the buffing treatment and to easily remove small particles.

While the present inventive concept has been described with reference to example embodiments thereof, it will be understood by those of ordinary skill in the art that various changes in form and details may be made thereto without departing from the spirit and scope of the present inventive concept.

What is claimed is:

1. A buffing treatment module comprising:
a buffing table that supports a substrate;
a buffing head located on the buffing table and configured to rotate; and
a buffing pad attached to a lower part of the buffing head and rotating while in contact with the substrate for performing buffing treatment on the substrate,
wherein the buffing pad comprises:
a base unit;
a plurality of protrusion units that protrude from a surface of the base unit and are spaced apart from each other in a circumferential direction of the base unit; and
a plurality of trench units positioned adjacent to the plurality of protrusion units, and extending from a center portion of the base unit to an edge portion of the base unit, wherein the plurality of trench units are spaced apart from each other in the circumferential direction of the base unit.

2. The buffing treatment module of claim 1, wherein the plurality of trench units are in contact with the plurality of protrusion units.

3. The buffing treatment module of claim 1, wherein the plurality of trench units are arranged at first sides of the protrusion units according to a rotation direction of the buffing head.

4. The buffing treatment module of claim 1, wherein the plurality of trench units are spaced apart from the plurality of protrusion units.

5. The buffing treatment module of claim 1, wherein the plurality of protrusion units comprise a plurality of long protrusion units and a plurality of short protrusion units, wherein a length of each of the plurality of long protrusion units is larger than a length of each of the plurality of short protrusion units in the radial direction of the base unit.

6. The buffing treatment module of claim 1, wherein the plurality of protrusion units comprise a plurality of short protrusion units that are shorter than the plurality of trench units in a radial direction of the base unit.

7. The buffing treatment module of claim 1, wherein the plurality of trench units have a first width at the edge portion of the base unit in the circumferential direction of the base unit and a second width at the center portion of the base unit in the circumferential direction of the base unit, wherein the first width is greater than the second width.

8. The buffing treatment module of claim 1, wherein the plurality of trench units comprise an inclined surface that is inclined from the surface of the base unit to an inside of the base unit.

9. The buffing treatment module of claim 1, wherein the plurality of trench units comprise a curved surface that is curved from the surface of the base unit to an inside of the base unit.

10. A buffing treatment module comprising:
a buffing table that supports a substrate;
a buffing head located on the buffing table and configured to rotate; and
a buffing pad attached to a lower part of the buffing head and rotating while in contact with the substrate for performing buffing treatment on the substrate,
wherein the buffing pad comprises:
a base unit having an outer circle and an inner circle that is located within the outer circle;
a plurality of protrusion units that protrude from a surface of the base unit, and that extend to a boundary of the inner circle, wherein the plurality of protrusion units are spaced apart from each other in a circumferential direction of the base unit; and
a plurality of trench units positioned adjacent to the plurality of protrusion units, and extending from the inner circle to the outer circle, wherein the plurality of trench units are spaced apart from each other in the circumferential direction of the base unit.

11. The buffing treatment module of claim 10, wherein the plurality of trench units are in contact with the plurality of protrusion units, and the plurality of trench units are arranged at front ends of the plurality of protrusion units according to a rotation direction of the buffing head.

12. The buffing treatment module of claim 10, wherein the plurality of protrusion units comprise a plurality of first protrusion units, and a plurality of second protrusion units, wherein the plurality of first protrusion units extend to the boundary of the inner circle.

13. The buffing treatment module of claim 12, wherein the plurality of trench units are in contact with the plurality of first protrusion units and the plurality of second protrusion units, and the plurality of trench units are arranged at front ends of the plurality of first protrusion units and the front ends of the plurality of second protrusion units according to a rotation direction of the buffing head.

14. The buffing treatment module of claim 10, wherein the plurality of protrusion units comprise a plurality of second protrusion units that are shorter than the plurality of trench units in a radial direction of the base unit, and the plurality of second protrusion units extend to the boundary of the inner circle.

15. The buffing treatment module of claim 14, wherein the plurality of trench units are in contact with the plurality of second protrusion units, and the plurality of trench units are arranged at front ends of the plurality of second protrusion units according to a rotation direction of the buffing head.

16. The buffing treatment module of claim 10, wherein the plurality of trench units have a first width at an edge portion of the base unit in the circumferential direction of the base unit and a second width at the inner circle of the base unit in the circumferential direction of the base unit, wherein the first width is greater than the second width.

17. A buffing treatment module comprising:
a buffing table that supports a substrate;
a buffing head located on the buffing table and configured to rotate; and
a buffing pad attached to a lower part of the buffing head and rotating while in contact with the substrate for performing buffing treatment on the substrate,
wherein the buffing pad comprises:
a circular base unit having an outer circle and an inner circle that is located within the outer circle;
a plurality of protrusion units that protrude from a surface of the base unit, and that extend to a boundary of the inner circle, wherein the plurality of protrusion units are spaced apart from each other in a circumferential direction of the base unit;
a plurality of trench units positioned adjacent to the plurality of protrusion units, and extending from the inner circle to the outer circle, wherein the plurality of trench units are spaced apart from each other; and
a central trench unit connected to the plurality of trench units inside the inner circle.

18. The buffing treatment module of claim 17, wherein the plurality of protrusion units comprise a plurality of short protrusion units that are shorter than the plurality of trench units in a radial direction of the base unit, wherein the plurality of short protrusion units are arranged in contact with the inner circle, and wherein the central trench unit is arranged in a partial area of the inner circle.

19. The buffing treatment module of claim 18, wherein the plurality of trench units are in contact with the plurality of short protrusion units, wherein the plurality of trench units are arranged at front ends of the short protrusion units according to a rotation direction of the buffing head, wherein the plurality of trench units have a first width at an edge portion of the base unit and a second width at a center portion of the base unit, and wherein the first width is greater than the second width.

20. The buffing treatment module of claim 17, wherein the plurality of protrusion units comprise a plurality of long protrusion units and a plurality of short protrusion units, wherein the plurality of long protrusion units are arranged in contact with the inner circle, and the central trench unit surrounds the inner circle and is installed in communication with the plurality of trench units.
